(19) United States
(12) Patent Application Publication
(10) Pub. No.: US 2024/0276751 A1
(43) Pub. Date: Aug. 15, 2024

(54) ORGANIC LIGHT EMITTING DEVICE

(71) Applicant: LG Display Co., Ltd., Seoul (KR)

(72) Inventors: Jeong-Eun WON, Paju-si (KR); Chun-Ki KIM, Paju-si (KR); Yo-Sub LEE, Paju-si (KR); Seung-Ryong JOUNG, Paju-si (KR)

(73) Assignee: LG Display Co., Ltd., Seoul (KR)

(21) Appl. No.: 18/537,084

(22) Filed: Dec. 12, 2023

(30) Foreign Application Priority Data
Jan. 27, 2023 (KR) 10-2023-0010983

(51) Int. Cl. H10K 50/12; H10K 50/155; H10K 50/165; H10K 85/30; H10K 85/60

(52) U.S. Cl. CPC H10K 50/12; H10K 50/155; H10K 50/165; H10K 85/342; H10K 85/636; H10K 85/6572; H10K 85/6574

(57) ABSTRACT

An organic light emitting device is disclosed, which comprises: a substrate; a cathode over the substrate; an anode disposed over the cathode; and an organic light emitting layer comprising a first emitting part, a second emitting part between the first emitting part and the anode and a third emitting part between the first and second emitting parts and positioned between the cathode and the anode, wherein the first emitting part comprises a first emitting material layer, and the second emitting part comprises a second emitting material layer, wherein the third emitting part comprises a third emitting material layer, and the third emitting material layer comprises a red emitting material layer and a green emitting material layer, wherein the green emitting material layer comprises a first p-type host, a first n-type host and a green dopant.

### CROSS-REFERENCE TO RELATED APPLICATIONS

The present application claims priority, under 35 U.S.C. § 119, to Korean Patent Application No. 10-2023-0010983 filed in the Republic of Korea on Jan. 27, 2023, which is hereby incorporated by reference in its entirety into the present application.

### BACKGROUND

### Technical Field

The present disclosure relates to an organic light emitting device, and more particularly, to an organic light emitting device such as a display device or a lighting device, which has improved driving voltage and/or emitting efficiency.

### Discussion of the Related Art

As demand increases for flat panel display devices that occupy a small space, an organic light emitting device including an organic light emitting diode (OLED) has become a focus of recent research and development.

The OLED includes a cathode as an electron injection electrode, an anode as a hole injection electrode and an emitting material layer therebetween. When electrons from the cathode and holes from the anode are provided into the emitting material layer, the electrons and holes are combined to generate an exciton, and the exciton is transformed from an excited state to a ground state. As a result, the light is emitted from the OLED.

An OLED has certain advantages. For instance, an OLED can be formed as a thin organic film less than 2000 Å, and the electrode configurations can implement unidirectional or bidirectional images. Also, the OLED can be formed on a flexible transparent substrate, e.g., a plastic substrate, and can be driven by low voltage. In addition, the OLED has low power consumption and high color sense.

The organic light emitting device includes an organic light emitting diode (OLED) including an anode, a cathode spaced apart from the anode and over the anode and an organic light emitting layer between the anode and the cathode. The organic light emitting device can require at least three thin film transistors and at least one storage capacitor for driving the OLED. Namely, a normal-structure organic light emitting device, where the anode, the organic light emitting layer and the cathode are sequentially stacked on a substrate, has a 3T1C structure so that an aperture ratio of the organic light emitting device is decreased. There remains a need in the art to provide an organic light emitting device with a higher aperture ratio, as well as improved driving voltage, emitting efficiency and lifespan.

### SUMMARY OF THE DISCLOSURE

Embodiments of the present disclosure are directed to an organic light emitting device that address one or more of the limitations and disadvantages of the related art.

An object of the present disclosure is to provide an organic light emitting device having high aperture ratio. In certain embodiments, the aperture ratio of a pixel region may be defined as the ratio of the light-sensitive area of a pixel region to the total area of that pixel region. The aperture ratio may be expressed as a percentage, e.g., the higher the aperture ratio, the more light is emitted in a given display area. In a preferred embodiment, the aperture ratio may be 50% or more, preferably 60% or more, preferably 70% or more, preferably 80% or more, or preferably 90% or more.

An object of the present disclosure is to provide an organic light emitting device having improved driving voltage, emitting efficiency, and/or lifespan. Further, the present disclosure provides a display device comprising a display panel configured to display an image, where the display panel includes a plurality of pixel regions disposed on a substrate, and each of the plurality of pixel regions includes the organic light emitting device.

Additional features and aspects will be set forth in the description that follows, and in part will be apparent from the description, or can be learned by practice of the present disclosure concepts provided herein. Other features and aspects of the present disclosure concepts can be realized and attained by the structure particularly pointed out in the written description, or derivable therefrom, and the claims hereof as well as the appended drawings.

As described herein, an aspect of the present disclosure is an organic light emitting device comprising a substrate; a cathode over the substrate; an anode disposed over the cathode; and an organic light emitting layer that is positioned between the cathode and anode. The organic light emitting layer includes a first emitting part, a second emitting part between the first emitting part and the anode and a third emitting part between the first and second emitting parts and positioned between the cathode and the anode. The first emitting part includes a first emitting material layer, and the second emitting part includes a second emitting material layer, and the third emitting part includes a third emitting material layer. The third emitting material layer includes a red emitting material layer and a green emitting material layer, wherein the green emitting material layer includes a first p-type host, a first n-type host and a green dopant.

In an aspect, an organic light emitting device, comprises a substrate; a cathode over the substrate; an anode disposed over the cathode; and an organic light emitting layer comprising a first emitting part, a second emitting part between the first emitting part and the anode and a third emitting part between the first and second emitting parts and positioned between the cathode and the anode. The first emitting part comprises a first emitting material layer, and the second emitting part comprises a second emitting material layer. The first emitting part further comprises a first electron transporting layer between the cathode and the first emitting material layer, and the second emitting part further comprises a second electron transporting layer between the second emitting material layer and the third emitting material layer. The first emitting material layer comprises a first lower layer having a first thickness of 750 Å to 850 Å, and a first upper layer having a second thickness of 50 Å to 150 Å. Further, the second emitting material layer comprises a second lower layer having a third thickness of 300 Å to 400 Å and a second upper layer having a fourth thickness of 50 Å to 150 Å. The third emitting part comprises a third emitting material layer, and the third emitting material layer comprises a red emitting material layer and a green emitting material layer, The green emitting material layer comprises a first p-type host, a first n-type host and a green dopant. Each of the first and second lower layers comprises a compound in Formula 7-1, as described below, and each of the first and second upper layers comprises a compound in Formula 7-2, as described below, or a compound represented by Formula 8, as described below.

In some aspects, the first emitting part further comprises a first hole transporting layer between the first emitting part and the third emitting part, and the first hole transporting layer comprises a compound in Formula 10-1, as described below, and a compound in Formula 10-2 as described below.

In some aspects, the third emitting part further comprises a third hole transporting layer between the green emitting material layer and the second electron transporting layer, and a thickness of the third hole transporting layer is greater than each of a thickness of the first hole transporting layer and a thickness of the second hole transporting layer.

In some aspects, a first charge generation layer comprising a first p-type charge generation layer and a second n-type charge generation layer and positioned between the first emitting part and the third emitting part, and a second charge generation layer comprising a second p-type charge generation layer and a second n-type charge generation layer and positioned between the second emitting part and the third emitting part, where the first p-type charge generation layer comprises a first host material and a first p-type dopant, and the second p-type charge generation layer comprises a second host material and a second p-type dopant. Each of a weight % of the first p-type dopant in the first p-type charge generation layer and a weight % of the second p-type dopant in the second p-type charge generation layer is smaller than a weight % of the p-type dopant in the hole injection layer.

Some aspects relate to a display device comprising: a display panel configured to display an image, and including a plurality of pixel regions, each of the plurality of pixel regions including the organic light emitting device as described herein.

It is to be understood that both the foregoing general description and the following detailed description are exemplary and explanatory and are intended to provide further explanation of the inventive concepts as claimed.

### BRIEF DESCRIPTION OF THE DRAWINGS

The accompanying drawings, which are included to provide a further understanding of the present disclosure and are incorporated in and constitute a part of this application, illustrate embodiments of the present disclosure and together with the description serve to explain principles of the present disclosure.

FIG. 1 is a schematic circuit diagram of an organic light emitting display device according to one or more embodiments of the present disclosure.

FIG. 2 is a schematic cross-sectional view of an organic light emitting display device according to one or more embodiments of the present disclosure.

FIG. 3 is a schematic cross-sectional view of an OLED according to one or more embodiments of the present disclosure.

FIG. 4A is a graph showing a current density according to a voltage in an OLED according to one or more embodiments of the present disclosure, and FIG. 4B is a graph showing an emitting efficiency according to a current density in an OLED according to one or more embodiments of the present disclosure.

FIG. 5A is a graph showing a current density according to a voltage in an organic light emitting display device, and FIG. 5B is a graph showing an emitting efficiency according to a current density in an organic light emitting display device, both according to one or more embodiments of the present disclosure.

FIG. 6 is a graph showing an emission intensity at wavelengths in an organic light emitting display device according to one or more embodiments of the present disclosure.

### DETAILED DESCRIPTION OF THE EMBODIMENTS

Reference will now be made in detail to aspects of the present disclosure, several examples of which are illustrated in the accompanying drawings. In the following, when a detailed description of well-known functions or configurations related to this document is determined to unnecessarily cloud a gist of the inventive concept, the detailed description thereof can be omitted. The progression of processing steps and/or operations described is an example; however, the sequence of steps and/or operations is not limited to that set forth herein and can be changed as is known in the art, with the exception of steps and/or operations necessarily occurring in a particular order. Like reference numerals designate like elements throughout. Names of the respective elements used in the following explanations are selected only for convenience of writing the specification and can be thus different from those used in actual products. All the components of each OLED and each organic light emitting display device according to all embodiments of the present disclosure are operatively coupled and configured.

Advantages and features of the present disclosure and methods of achieving them will be apparent with reference to the aspects described below in detail with the accompanying drawings. However, the present disclosure is not limited to the aspects disclosed below, but can be realized in a variety of different forms.

The shapes, sizes, proportions, angles, numbers, thicknesses, and the like disclosed in the drawings for explaining certain aspects of the present disclosure are illustrative, and the present disclosure is not limited to the illustrated matters. The same reference numerals refer to the same elements throughout the specification. When terms such as “including,” “having,” “comprising,” etc. are used in this specification, other parts can be added unless “only” is used. When a component is expressed in the singular, cases including the plural are included unless a specific statement is described.

In construing an element, the element is construed as including an error or tolerance range although there is no explicit description of such an error or tolerance range.

In describing a position relationship, for example, when a position relation between two parts is described as, for example, “on,” “over,” “above,” “under,” “below,” and “next,” one or more other parts can be disposed between the two parts unless a more limiting term, such as “just” or “direct(ly)” is used.

In describing a time relationship, for example, when the temporal order is described as, for example, “after,” “subsequent,” “next,” and “before,” a case that is not continuous can be included unless a more limiting term, such as “just,” “immediate(ly),” or “direct(ly)” is used.

It will be understood that, although the terms “first,” “second,” etc. can be used herein to describe various elements, these elements should not be limited by these terms. These terms are only used to distinguish one element from another and may not define order or sequence. For example, a first element could be termed a second element, and, similarly, a second element could be termed a first element, without departing from the scope of the present disclosure.

Features of various aspects of the present disclosure can be partially or overall coupled to or combined with each other, and can be variously inter-operated with each other and driven technically as those skilled in the art can sufficiently understand. The aspects of the present disclosure can be carried out independently from each other, or can be carried out together in co-dependent relationship.

In the present disclosure, an organic light emitting device can be an organic light emitting display device or an organic lighting device. As an example, an organic light emitting display device, which is a display device including the OLED of the present disclosure, will be mainly described.

Reference will now be made in detail to some of the examples and preferred embodiments, which are illustrated in the accompanying drawings. In the present disclosure, an organic light emitting device including the OLED can be an organic light emitting display device or an organic lighting device, but can include other devices such as testing devices, medical devices, etc.

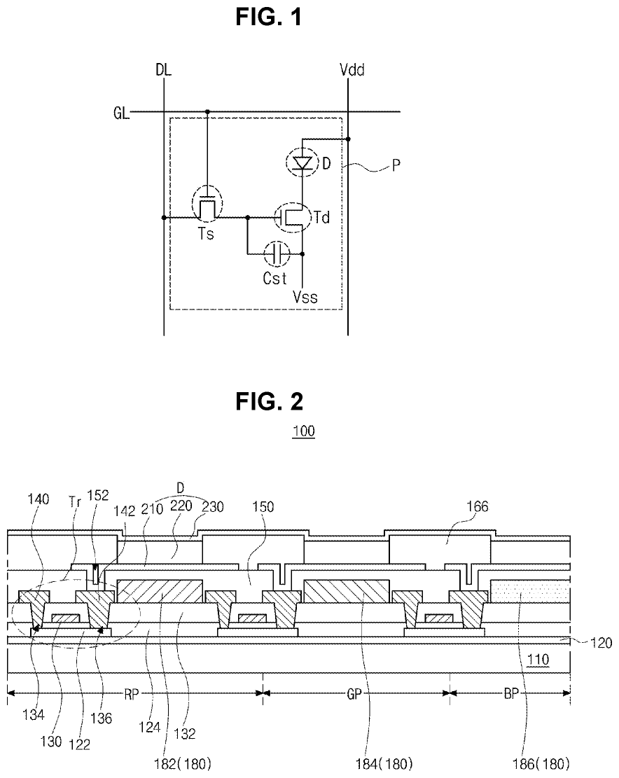

FIG. 1 is a schematic circuit diagram of an organic light emitting display device according to one or more embodiments of the present disclosure.

As shown in FIG. 1, an organic light emitting display device includes a gate line GL and a data line DL crossing each other to define a pixel region P. The organic light emitting display device further includes a high potential voltage line Vdd and a low potential voltage line Vss. In the pixel region P, a switching thin film transistor TFT Ts, a driving TFT Td, a storage capacitor Cst and an OLED D are disposed. The pixel region P can include a red pixel region, a green pixel region and a blue pixel region, but other variations are possible. For instance, the pixel region P can include a red pixel region, a green pixel region, a blue pixel region and a white pixel region. The organic light emitting display device includes a plurality of such pixel regions P which can be arranged in a matrix configuration or other suitable configuration. The organic light emitting display device can further include other components such as a timing controller, a scan driver, a data driver, a power source, etc., and can be a flexible, bendable, or wearable device, which can include a touch function. The organic light emitting display device includes a plurality of such pixel regions P.

In each pixel region P, the switching TFT Ts is connected to the gate line GL and the data line DL, and the driving TFT Td is connected to the switching TFT Ts and the low potential voltage line Vss. The storage capacitor Cst is connected to a gate electrode of the driving TFT Td and the low potential voltage line Vss, and the OLED D is connected to the driving TFT Td and the high potential voltage line Vdd.

In the organic light emitting display device, when the switching TFT Ts is turned on by a gate signal (scan signal) applied through the gate line GL (scan line), a data signal from the data line DL is applied to the gate electrode of the driving TFT Td and an electrode of the storage capacitor Cst.

When the driving TFT Td is turned on by the data signal, an electric current flows from the high potential voltage line Vdd to the low potential voltage line Vss so that the OLED D can emit light.

The storage capacitor Cst serves to maintain the voltage of the gate electrode of the driving TFT Td when the switching TFT Ts is turned off.

As a result, the organic light emitting display device displays a desired image.

The OLED D has an inverted-structure, where a cathode, an organic light emitting layer and an anode are sequentially stacked over a substrate, and can be driven by two TFTs and one storage capacitor. In other words, the organic light emitting display device has a 2T1C structure so that an aperture ratio of the organic light emitting display device is improved.

FIG. 2 is a schematic cross-sectional view of an organic light emitting display device according to a first embodiment of the present disclosure.

As shown in FIG. 2, the organic light emitting display device 100 includes a substrate 110, where a red pixel region RP, a green pixel region GP and a blue pixel region BP are defined, a TFT Tr over the substrate 110, an OLED D, which is positioned over and connected to the TFT Tr, and a color filter layer 180 between the OLED D and the substrate 110. The pixel region configuration of the organic light emitting display device 100 can correspond to that of FIG. 1, but is not limited thereto. Obviously, so many variations of the organic light emitting display device 100 can be possible, e.g., a white pixel region WP can be further included. In certain embodiments, the organic light emitting display device 100 includes a plurality of pixel regions including a plurality of red pixel regions RP, a plurality of green pixel regions GP and a plurality of blue pixel regions BP, and the plurality of pixel regions can be disposed in a matrix configuration or other suitable configurations. The plurality of pixel regions are part of a display panel included in the organic light emitting display device 100.

The substrate 110 can be a glass substrate or a flexible substrate. For example, the substrate 110 can be a polyimide (PI) substrate, a polyethersulfone (PES) substrate, a polyethylenenaphthalate (PEN) substrate, a polyethylene terephthalate (PET) substrate or a polycarbonate (PC) substrate.

A buffer layer 120 is formed on the substrate 110, and the TFT Tr corresponding to each of the red, green and blue pixel regions RP, GP and BP is formed on the buffer layer 120. The buffer layer 120 can be omitted in certain embodiments, and the TFT Tr can be formed on the substrate 110.

A semiconductor layer 122 is formed on the buffer layer 120. The semiconductor layer 122 can include an oxide semiconductor material or polycrystalline silicon. When the semiconductor layer 122 includes the oxide semiconductor material, a light-shielding pattern can be formed under the semiconductor layer 122. The light to the semiconductor layer 122 is shielded or blocked by the light-shielding pattern such that thermal degradation of the semiconductor layer 122 can be prevented. On the other hand, when the semiconductor layer 122 includes polycrystalline silicon, impurities can be doped into both sides of the semiconductor layer 122.

A gate insulating layer 124 of an insulating material is formed on the semiconductor layer 122. The gate insulating layer 124 can be formed of an inorganic insulating material such as silicon oxide (SiOx) or silicon nitride (SiNx).

A gate electrode 130, which is formed of a conductive material, e.g., metal, is formed on the gate insulating layer 124 to correspond to a center of the semiconductor layer 122. In FIG. 2, the gate insulating layer 124 is formed on an entire surface of the substrate 110. Alternatively, the gate insulating layer 124 can be patterned to have the same shape as the gate electrode 130.

An interlayer insulating layer 132, which is formed of an insulating material, is formed on the gate electrode 130. The interlayer insulating layer 132 can be formed of an inorganic insulating material, e.g., silicon oxide or silicon nitride, or an organic insulating material, e.g., benzocyclobutene or photo-acryl.

The interlayer insulating layer 132 includes first and second contact holes 134 and 136 exposing both sides of the semiconductor layer 122. The first and second contact holes 134 and 136 are positioned at both sides of the gate electrode 130 to be spaced apart from the gate electrode 130. The first and second contact holes 134 and 136 are formed through the gate insulating layer 124 and the interlayer insulating layer 132. Alternatively, when the gate insulating layer 124 is patterned to have the same shape as the gate electrode 130, the first and second contact holes 134 and 136 is formed only through the interlayer insulating layer 132.

A source electrode 140 and a drain electrode 142, which are formed of a conductive material, e.g., metal, are formed on the interlayer insulating layer 132. The source electrode 140 and the drain electrode 142 are spaced apart from each other with respect to the gate electrode 130 and respectively contact both sides of the semiconductor layer 122 through the first and second contact holes 134 and 136. In certain embodiments, the designation of the source and drain electrodes 140 and 142 can be switched with each other depending on the type and configuration of a transistor.

The semiconductor layer 122, the gate electrode 130, the source electrode 140 and the drain electrode 142 constitute the TFT Tr, and the TFT Tr can be an n-type TFT, but can be a p-type TFT. The TFT Tr serves as a driving element. Namely, the TFT Tr can correspond to the driving TFT Td (of FIG. 1).

In FIG. 2, the gate electrode 130, the source electrode 140, and the drain electrode 142 are positioned over the semiconductor layer 122. Namely, the TFT Tr has a coplanar structure. Alternatively, in the TFT Tr, the gate electrode can be positioned under the semiconductor layer, and the source and drain electrodes can be positioned over the semiconductor layer such that the TFT Tr can have an inverted staggered structure. In this instance, the semiconductor layer can include amorphous silicon.

The color filter layer 180 is formed on the interlayer insulating layer 132. The color filter layer 180 includes red, green and blue color filters 182, 184 and 186 respectively corresponding to the red, green and blue pixel regions RP, GP and BP.

The red color filter 182 can include at least one of a red dye and a red pigment, the green color filter 184 can include at least one of a green dye and a green pigment, and the blue color filter 186 can include at least one of a blue dye and a blue pigment.

In certain embodiments, the gate line and the data line cross each other to define the pixel region, and the switching TFT is formed to be connected to the gate and data lines. The switching TFT is connected to the TFT Tr as the driving element. In addition, the high potential voltage line and the low potential voltage line are formed over the substrate 110, and the storage capacitor for maintaining the voltage of the gate electrode of the TFT Tr in one frame can be further formed.

A planarization layer 150 is formed on the color filter layer 180 and the TFT Tr and over an entire surface of the substrate 110. The planarization layer 150 has a flat top surface and includes a drain contact hole 152 exposing the drain electrode 142 of the TFT Tr.

The OLED D is positioned on the planarization layer 150 and includes a cathode 210, which is connected to the drain electrode 142 of the TFT Tr through the drain contact hole 152, an organic light emitting layer 220 on the cathode 210 and an anode 230 on the organic light emitting layer 220. The OLED D is positioned in each of the red, green and blue pixel regions RP, GP and BP and emits white light.

The cathode 210 is separately formed in each of the red, green and blue pixel regions RP, GP and BP and on the planarization layer 150. The cathode 210 can be formed of a transparent conductive oxide (TCO) having a relatively high work function. The cathode 210 can be a transparent electrode. For example, the cathode 210 can be formed of indium-tin-oxide (ITO), indium-zinc-oxide (IZO) or indium-tin-zinc-oxide (ITZO).

A bank layer 166 is formed on the planarization layer 150 to cover an edge of the cathode 210. For instance, the bank layer 166 is positioned at a boundary of the pixel region and exposes a center of the cathode 210 in the pixel region. Since the OLED D emits white light in each of the red, green and blue pixel regions RP, GP and BP, the organic light emitting layer 220 can be formed as a common layer without separation. The bank layer 166 can be formed to prevent current leakage at an edge of the cathode 210. The bank layer 166 can be omitted in certain embodiments.

The organic light emitting layer 220 is formed on the cathode 210. The organic light emitting layer 220 can include a first emitting part positioned on the cathode 210 and including a first emitting material layer (EML), a second emitting part positioned between the first emitting part and the anode 230 and including a second EML and a third emitting part positioned between the first and second emitting parts and including a third EML. The organic light emitting layer 220 can further include a first charge generation layer (CGL) between the first and third emitting parts and a second CGL between the second and third emitting parts.

Each of the first and second EMLs can be a blue EML, and the third EML can include a red EML and a green EML. In addition, the third EML can further include a yellow-green EML.

The anode 230 is formed over the substrate 110 where the organic light emitting layer 220 is formed. The anode 230 is disposed over an entire surface of a display area and can include a metallic material having high reflectance. The anode 230 can be a reflective electrode. For example, the anode 230 can include a material selected from the group consisting of aluminum (Al), magnesium (Mg), calcium (Ca), silver (Ag), their alloy and their combination.

Namely, the OLED D can be an inverted-structure white OLED, but other variations are possible.

An encapsulation layer (or an encapsulation film) can be formed to prevent penetration of moisture into the OLED D. For example, the encapsulation film can include a first inorganic insulating layer, an organic insulating layer and a second inorganic insulating layer sequentially stacked, but it is not limited thereto.

In addition, a metal plate can be disposed on the encapsulation layer, but other layers can be formed instead.

Moreover, a polarization plate for reducing an ambient light reflection can be disposed at an outer side of the substrate 110. For example, the polarization plate can be a circular polarization plate.

In FIG. 2, the color filter layer 180 is positioned between the OLED D and the interlayer insulating layer 132. Alternatively, a position of the color filter layer 180 can be adjusted between the OLED D and the substrate 110.

A color conversion layer can be formed between the OLED D and the color filter layer 180. The color conversion layer can include a red color conversion layer, a green color conversion layer and a blue color conversion layer respectively corresponding to the red, green and blue pixel regions RP, GP and BP. The white light from the OLED D is converted into the red light, the green light and the blue light by the red, green and blue color conversion layer, respectively.

As described above, the white light from the OLED D passes through the red, green and blue color filters 182, 184 and 186 respectively corresponding to the red, green and blue pixel regions RP, GP and BP so that the red, green and blue light can be displayed in the red, green and blue pixel regions RP, GP and BP, respectively.

In FIG. 2, the OLED D emitting the white light is used for a display device. Alternatively, the OLED D can be formed on an entire surface of a substrate without at least one of the driving element and the color filter layer to be used for a lighting device. The display device and the lighting device each including the OLED D of the present disclosure can be referred to as an organic light emitting device.

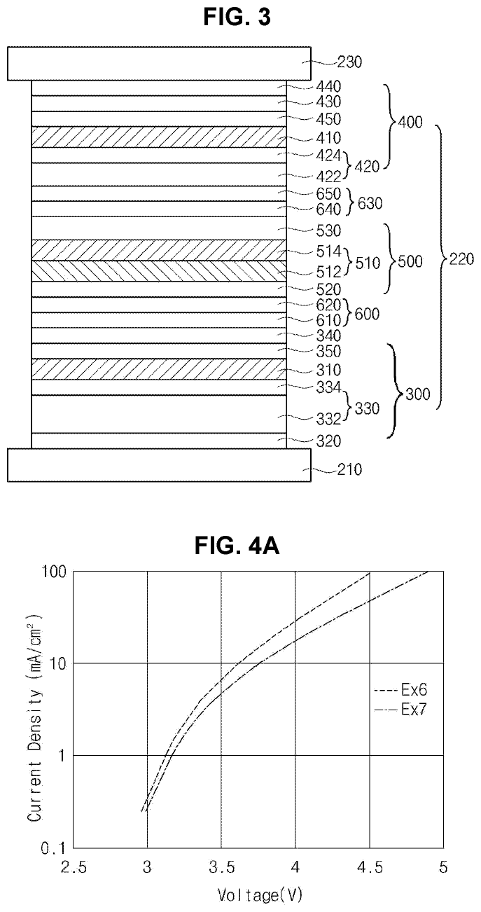

FIG. 3 is a schematic cross-sectional view illustrating an example of an OLED according to an embodiment of the present disclosure. The OLED configuration of FIG. 3 can be used as the OLED of FIGS. 1 and 2 or other figures or embodiments of the present disclosure.

As shown in FIG. 3, the OLED D includes the cathode 210 connected to the driving thin film transistor (TFT), the anode 230 facing the cathode 210 and an organic light emitting layer 220 between the cathode 210 and the anode 230, and the organic light emitting layer 220 includes a first emitting part 300 including a first emitting material layer (EML) 310, an electron injection layer (EIL) 320 and a first electron transporting layer (ETL) 330, a second emitting part 400 including a second EML 410, a second ETL 420, a second hole transporting layer (HTL) 430 and a hole injection layer (HIL) 440 and a third emitting part 500 including a third EML 510.

In addition, the organic light emitting layer 220 can further include a first CGL 600 between the first and third emitting parts 300 and 500 and a second CGL 630 between the second and third emitting parts 400 and 500.

In an aspect of the present disclosure, the cathode 210 can be formed of ITO and can have a thickness of 1000 Å to 1200 Å, preferably 900 Å to 1100 Å, or preferably 700 Å to 900 Å.

In an aspect of the present disclosure, the anode 230 can be formed of Al and can have a thickness of 900 Å to 1100 Å, preferably 950 Å to 1050 Å, or preferably 1000 Å.

The first EML 310 of the first emitting part 300 is a blue EML. In the first emitting part 300, the EIL 320 is positioned between the first EML 310 and the cathode 210, and the first ETL 330 is positioned between the first EML 310 and the EIL 320. The EIL 320 can contact the cathode 210.

The first emitting part 300 can further include a first HTL 340 on the first EML 310. In addition, the first emitting part 300 can further include a first electron blocking layer (EBL) 350 between the first EML 310 and the first HTL 340.

The second EML 410 of the second emitting part 400 is a blue EML. In the second emitting part 400, the second ETL 420 is positioned under the second EML 410, the second HTL 430 is positioned between the second EML 410 and the anode 230, and the HIL 440 is positioned between the second HTL 430 and the anode 230.

The second emitting part 400 can further include a second EBL 450 between the second EML 410 and the second HTL 430. In certain embodiments, the second emitting part 400 can further include a p-type dopant layer between the HIL 440 and the anode.

In the third emitting part 500, the third EML 510 includes a red EML 512 and a green EML 514. The red EML 512 can be positioned between the first emitting part 300 and the green EML 514.

The third emitting part 500 can further include at least one of a third ETL 520 under the third EML 510 and a third HTL 530 on the third EML 510.

The first EML 310 includes a first blue host and a first blue dopant, and the second EML 410 includes a second blue host and a second blue dopant.

The first blue host and the second blue host can be same or different, and the first blue dopant and the second blue dopant can be same or different.

Each of the first and second blue dopants can be a fluorescent material.

Alternatively, each of the first and second blue dopants can be a phosphorescent material or a delayed fluorescent material.

For example, each of the first and second blue hosts can independently be one of mCP, 9-(3-(9H-carbazol-9-yl)phenyl)-9H-carbazole-3-carbonitrile (mCP—CN), mCBP, CBP—CN, 9-(3-(9H-Carbazol-9-yl)phenyl)-3-(diphenylphosphoryl)-9H-carbazole (mCPPO1) 3,5-Di(9H-carbazol-9-yl)biphenyl (Ph-mCP), TSPO1, 9-(3′-(9H-carbazol-9-yl)-[1,1′-biphenyl]-3-yl)-9H-pyrido[2,3-b]indole (CzBPCb), bis(2-methylphenyl)diphenylsilane (UGH-1), 1,4-bis(triphenylsilyl)benzene (UGH-2), 1,3-bis(triphenylsilyl)benzene (UGH-3), 9,9-spirobifluoren-2-yl-diphenyl-phosphine oxide (SPPO1), and 9,9′-(5-(triphenylsilyl)-1,3-phenylene)bis(9H-carbazole) (SimCP).

Each of the first and second blue dopants can independently be one of perylene, 4,4′-bis[4-(di-p-tolylamino)styryl]biphenyl (DPAVBi), 4-(di-p-tolylamino)-4,4′-[(di-p-tolylamino)styryl]stilbene (DPAVB), 4,4′-bis[4-(diphenylamino)styryl]biphenyl (BDAVBi), 2,7-bis(4-diphenylamino)styryl)-9,9-spirofluorene (spiro-DPVBi), [1,4-bis[2-[4-[N,N-di(p-tolyl)amino]phenyl]vinyl] benzene (DSB), 1,4-di-[4-(N,N-diphenyl)amino]styryl-benzene (DSA), 2,5,8,11-tetra-tetr-butylperylene (TBPe), bis(2-hydroxylphenyl)-pyridine)beryllium (Bepp₂), 9-(9-Phenylcarbazole-3-yl)-10-(naphthalene-1-yl)anthracene (PCAN), mer-tris(1-phenyl-3-methylimidazolin-2-ylidene-C,C(2)′iridium(III) (mer-Ir(pmi)₃), fac-Tris(1,3-diphenyl-benzimidazolin-2-ylidene-C,C(2)′iridium(III) (fac-Ir(dpbic)₃), bis(3,4,5-trifluoro-2-(2-pyridyl)phenyl-(2-carboxypyridyl)iridium(III) (Ir(tfpd)₂pic), tris(2-(4,6-difluorophenyl)pyridine))iridium(III) (Ir(Fppy)₃), and bis[2-(4,6-difluorophenyl)pyridinato-C2,N](picolinato)iridium(III) (Firpic).

In an aspect of the present disclosure, each of the first and second blue hosts can be a compound in Formula 1-1, and each of the first and second blue dopants can be a compound in Formula 1-2.

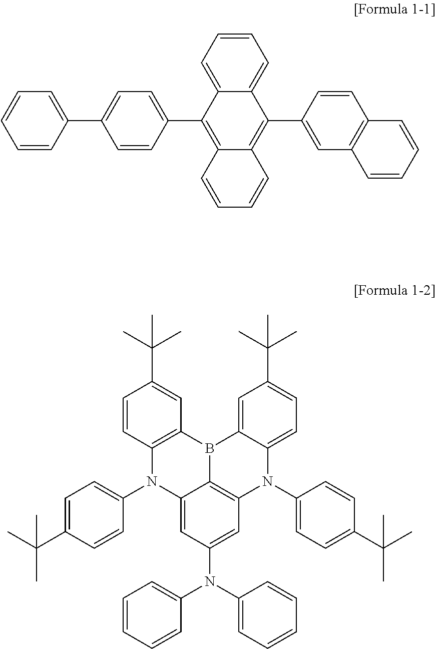

Each of a weight % of the first blue dopant in the first EML 310 and a weight % of the second blue dopant in the second EML 410 can be in a range of 1 to 5. The weight % of the first blue dopant in the first EML 310 and the weight % of the second blue dopant in the second EML 410 can be same or different.

Each of the first and second EMLs 310 and 410 can have a thickness of 200 to 350 Å. In an aspect of the present disclosure, a thickness of the first EML 310 can be smaller than that of the second EML 410.

In the third EML 500, a thickness of the red EML 512 can be smaller than that of the green EML 514. In an aspect of the present disclosure, the red EML 512 can have a thickness of 100 Å to 200 Å, and the green EML 514 can have a thickness of 250 to 350 Å.

The red EML 512 can include a red host and a red dopant. For example, the red host can be a phosphorescent compound.

The red host can be selected from the group consisting of mCP—CN, CBP, mCBP, mCP, DPEPO, 2,8-bis(diphenylphosphoryl)dibenzothiophene (PPT), 1,3,5-tri[(3-pyridyl)-phen-3-yl]benzene (TmPyPB), 2,6-di(9H-carbazol-9-yl)pyridine (PYD-2Cz), 2,8-di(9H-carbazol-9-yl)dibenzothiophene (DCzDBT), 3′,5′-di(carbazol-9-yl)-[1,1′-biphenyl]-3,5-dicarbonitrile (DCzTPA), 4′-(9H-carbazol-9-yl)biphenyl-3,5-dicarbonitrile (pCzB-2CN), 3′-(9H-carbazol-9-yl)biphenyl-3,5-dicarbonitrile (mCzB-2CN), TSPO1, 9-(9-phenyl-9H-carbazol-6-yl)-9H-carbazole (CCP), 4-(3-(triphenylen-2-yl)phenyl)dibenzo[b,d]thiophene, 9-(4-(9H-carbazol-9-yl)phenyl)-9H-3,9′-bicarbazole, 9-(3-(9H-carbazol-9-yl)phenyl)-9H-3,9′-bicarbazole, 9-(6-(9H-carbazol-9-yl)pyridin-3-yl)-9H-3,9′-bicabazole, 9,9′-diphenyl-9H,9′H-3,3′-bicarbazole (BCzPh), 1,3,5-tris(carbazole-9-yl)benzene (TCP), TCTA, 4,4′-bis(carbazole-9-yl)-2,2′-dimethylbiphenyl (CDBP), 2,7-bis(carbazole-9-yl)-9,9-dimethylfluorene (DMFL-CBP), 2,2′,7,7′-tetrakis(carbazole-9-yl)-9,9-spirofluorene (Spiro-CBP), and 3,6-bis(carbazole-9-yl)-9-(2-ethyl-hexyl)-9H-carbazole (TCz1), but it is not limited thereto.

The red dopant can be selected from the group consisting of [bis(2-(4,6-dimethyl)phenylquinoline)](2,2,6,6-tetramethylheptane-3,5-dionate)iridium(III), bis[2-(4-n-hexylphenyl)quinoline](acetylacetonate)iridium(III) (Hex-Ir(phq)₂(acac)), tris[2-(4-n-hexylphenyl)quinoline]iridium(III) (Hex-Ir(phq)₃), tris[2-phenyl-4-methylquinoline]iridium(III) (Ir(Mphq)₃), bis(2-phenylquinoline)(2,2,6,6-tetramethylheptene-3,5-dionate)iridium(III) (Ir(dpm)PQ₂), bis(phenylisoquinoline)(2,2,6,6-tetramethylheptene-3,5-dionate)iridium(III) (Ir(dpm)(piq)₂), bis[(4-n-hexylphenyl)isoquinoline](acetylacetonate)iridium(III) (Hex-Ir(piq)₂(acac)), tris[2-(4-n-hexylphenyl)quinoline]iridium(III) (Hex-Ir(piq)₃), tris(2-(3-methylphenyl)-7-methyl-quinolato)iridium (Ir(dmpq)₃), bis[2-(2-methylphenyl)-7-methyl-quinoline](acetylacetonate)iridium(III) (Ir(dmpq)₂(acac)), bis[2-(3,5-dimethylphenyl)-4-methyl-quinoline](acetylacetonate)iridium(III) (Ir(mphmq)₂(acac)), and tris(dibenzoylmethane)mono(1,10-phenanthroline)europium(III) (Eu(dbm)₃(phen)), but it is not limited thereto.

In an aspect of the present disclosure, in the red EML 512, the red host can include a second p-type host represented by Formula 2-1 and a second n-type host represented by Formula 2-2, and the red dopant can be a compound represented by Formula 2-3. A weight % of the red dopant can be in a range of 1 to 5. Alternatively, the second n-type host is represented by Formula 15:

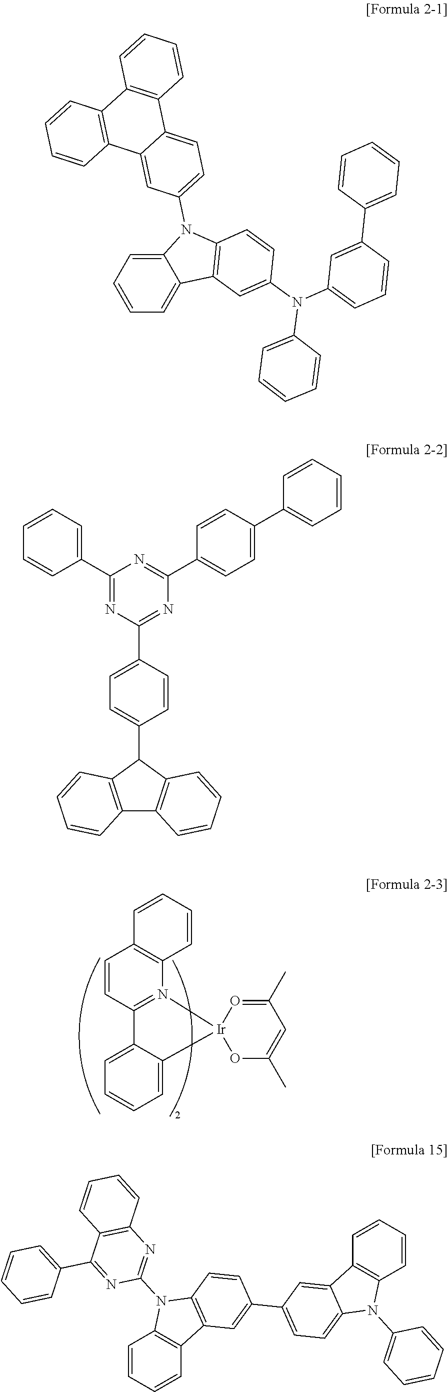

The green EML 514 can include a green host and a green dopant. For example, the green host can be a phosphorescent compound.

The green host can be selected from the group consisting of mCP—CN, CBP, mCBP, mCP, DPEPO, 2,8-bis(diphenylphosphoryl)dibenzothiophene (PPT), TmPyPB, PYD-2Cz, 2,8-di(9H-carbazol-9-yl)dibenzothiophene (DCzDBT), 3′,5′-di(carbazol-9-yl)-[1,1′-biphenyl]-3,5-dicarbonitrile (DCzTPA), 4′-(9H-carbazol-9-yl)biphenyl-3,5-dicarbonitrile (pCzB-2CN), 3′-(9H-carbazol-9-yl)biphenyl-3,5-dicarbonitrile (mCzB-2CN), TSPO1, and 9-(9-phenyl-9H-carbazol-6-yl)-9H-carbazole (CCP), but it is not limited thereto.

The green dopant can be selected from the group consisting of [bis(2-phenylpyridine)](pyridyl-2-benzofuro[2,3-b]pyridine)iridium), tris[2-phenylpyridine]iridium(III) (Ir(ppy)₃), fac-tris(2-phenylpyridine)iridium(III) (fac-Ir(ppy)₃), bis(2-phenylpyridine)(acetylacetonate)iridium(III) (Ir(ppy)₂(acac)), tris[2-(p-tolyl)pyridine]iridium(III) (Ir(mppy)₃), bis(2-(naphthalene-2-yl)pyridine)(acetylacetonate)iridium(III) (Ir(npy)₂acac), tris(2-phenyl-3-methyl-pyridine)iridium (Ir(3mppy)₃), and fac-tris(2-(3-p-xylyl)phenyl)pyridine iridium(III) (TEG), but it is not limited thereto.

In an aspect of the present disclosure, in the green EML 514, the green host can include a first p-type host and a first n-type host, and the green dopant can be a green phosphorescent dopant. In this case, a weight % of the green phosphorescent dopant in the green EML 514 can be greater than a weight % of the red dopant in the red EML 512. A weight % of the green dopant can be in a range of 5 to 15.

The first p-type host may be represented by Formula 16.

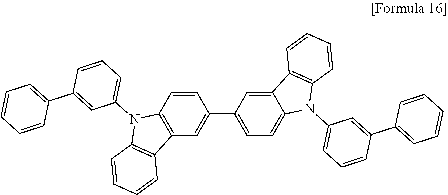 [SMILES: c1ccc(-c2cccc(-n3c4ccccc4c4cc(-c5ccc6c(c5)c5ccccc5n6-c5cccc(-c6ccccc6)c5)ccc43)c2)cc1]

The first p-type host can be represented by Formula 3.

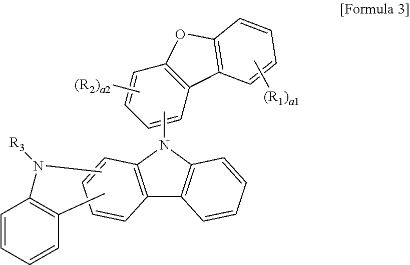

In Formula 3, a1 is an integer of 0 to 4, and a2 is an integer of 0 to 3, and each of R₁, R₂ and R₃ is independently selected from the group consisting of a substituted or unsubstituted C1 to C10 alkyl group, a substituted or unsubstituted C3 to C30 cycloalkyl group, a substituted or unsubstituted C6 to C30 arylamino group, a substituted or unsubstituted C6 to C30 aryl group and a substituted or unsubstituted C3 to C30 heteroaryl group.

In the present disclosure, without specific definition, a substituent of an alkyl group, a cycloalkyl group, an arylamino group, an aryl group and a heteroaryl group can be selected from the group consisting of deuterium, halogen, cyano, a substituted or unsubstituted C1 to C10 alkyl group, a substituted or unsubstituted C3 to C30 cycloalkyl group, a substituted or unsubstituted C6 to C30 arylamino group, a substituted or unsubstituted C6 to C30 aryl group and a substituted or unsubstituted C3 to C30 heteroaryl group.

In the present disclosure, without specific definition, a C1 to C10 alkyl group can be selected from the group consisting of methyl, ethyl, propyl and butyl, e.g., tert-butyl.

In the present disclosure, without specific definition, a C3 to C30 cycloalkyl group can be selected from the group consisting of cyclopropyl, cyclobutyl, cyclopentyl, cyclohexyl and adamantanyl.

In the present disclosure, without specific definition, a C6 to C30 aryl group can be selected from the group consisting of phenyl, biphenyl, terphenyl, naphthyl, anthracenyl, pentalenyl, indenyl, indenoindenyl, heptalenyl, biphenylenyl, indacenyl, phenanthrenyl, benzophenanthrenyl, dibenzophenanthrenyl, azulenyl, pyrenyl, fluoranthenyl, triphenylenyl, chrysenyl, tetraphenyl, tetrasenyl, picenyl, pentaphenyl, pentacenyl, fluorenyl, indenofluorenyl and spiro-fluorenyl.

In the present disclosure, without specific definition, a C6 to C30 arylene group can be selected from the group consisting of phenylene, biphenylene, terphenylene, naphthylene, anthracenylene, pentalenylene, indenylene, indenoindenylene, heptalenylene, biphenylenylene, indacenylene, phenanthrenylene, benzophenanthrenylene, dibenzophenanthrenylene, azulenylene, pyrenylene, fluoranthenylene, triphenylenylene, chrysenylene, tetraphenylene, tetrasenylene, picenylene, pentaphenylene, pentacenylene, fluorenylene, indenofluorenylene and spiro-fluorenylene.

In the present disclosure, without specific definition, a C3 to C30 heteroaryl group can be selected from the group consisting of pyrrolyl, pyridinyl, pyrimidinyl, pyrazinyl, pyridazinyl, triazinyl, tetrazinyl, imidazolyl, pyrazolyl, indolyl, isoindolyl, indazolyl, indolizinyl, pyrrolizinyl, carbazolyl, benzocarbazolyl, dibenzocarbazolyl, indolocarbazolyl, indenocarbazolyl, benzofurocarbazolyl, benzothienocarbazolyl, quinolinyl, isoquinolinyl, phthalazinyl, quinoxalinyl, cinnolinyl, quinazolinyl, quinozolinyl, quinolinyl, purinyl, phthalazinyl, quinoxalinyl, benzoquinolinyl, benzoisoquinolinyl, benzoquinazolinyl, benzoquinoxalinyl, acridinyl, phenanthrolinyl, perimidinyl, phenanthridinyl, pteridinyl, naphtharidinyl, furanyl, oxazinyl, oxazolyl, oxadiazolyl, triazolyl, dioxynyl, benzofuranyl, dibenzofuranyl, thiopyranyl, xanthenyl, chromanyl, isochromanyl, thioazinyl, thiophenyl, benzothiophenyl, dibenzothiophenyl, difuropyrazinyl, benzofurodibenzofuranyl, benzothienobenzothiophenyl, benzothienodibenzothiophenyl, benzothienobenzofuranyl, and benzothienodibenzofuranyl.

In the present disclosure, without specific definition, a C3 to C30 heteroarylene group can be selected from the group consisting of pyrrolylene, pyridinylene, pyrimidinylene, pyrazinylene, pyridazinylene, triazinylene, tetrazinylene, imidazolylene, pyrazolylene, indolylene, isoindolylene, indazolylene, indolizinylene, pyrrolizinylene, carbazolylene, benzocarbazolylene, dibenzocarbazolylene, indolocarbazolylene, indenocarbazolylene, benzofurocarbazolylene, benzothienocarbazolylene, quinolinylene, isoquinolinylene, phthalazinylene, quinoxalinylene, cinnolinylene, quinazolinylene, quinozolinylene, quinolinylene, purinylene, phthalazinylene, quinoxalinylene, benzoquinolinylene, benzoisoquinolinylene, benzoquinazolinylene, benzoquinoxalinylene, acridinylene, phenanthrolinylene, perimidinylene, phenanthridinylene, pteridinylene, naphtharidinylene, furanylene, oxazinylene, oxazolylene, oxadiazolylene, triazolylene, dioxynylene, benzofuranyenel, dibenzofuranylene, thiopyranylene, xanthenylene, chromanylene, isochromanylene, thioazinylene, thiophenylene, benzothiophenylene, dibenzothiophenylene, difuropyrazinylene, benzofurodibenzofuranylene, benzothienobenzothiophenylene, benzothienodibenzothiophenylene, benzothienobenzofuranylene, and benzothienodibenzofuranylene.

In Formula 3, one of a1 and a2 can be 1, and the other one of a1 and a2 can be 0.

In Formula 3, each of R₁, R₂ and R₃ can be independently selected from the group consisting of a substituted or unsubstituted C6 to C30 aryl group, e.g., phenyl or biphenyl, and a substituted or unsubstituted C3 to C30 heteroaryl group, e.g., dibenzofuranyl, dibenzothiophenyl, carbazolyl or phenylcarbazolyl.

For example, the first p-type host can be one of compounds in Formula 4.

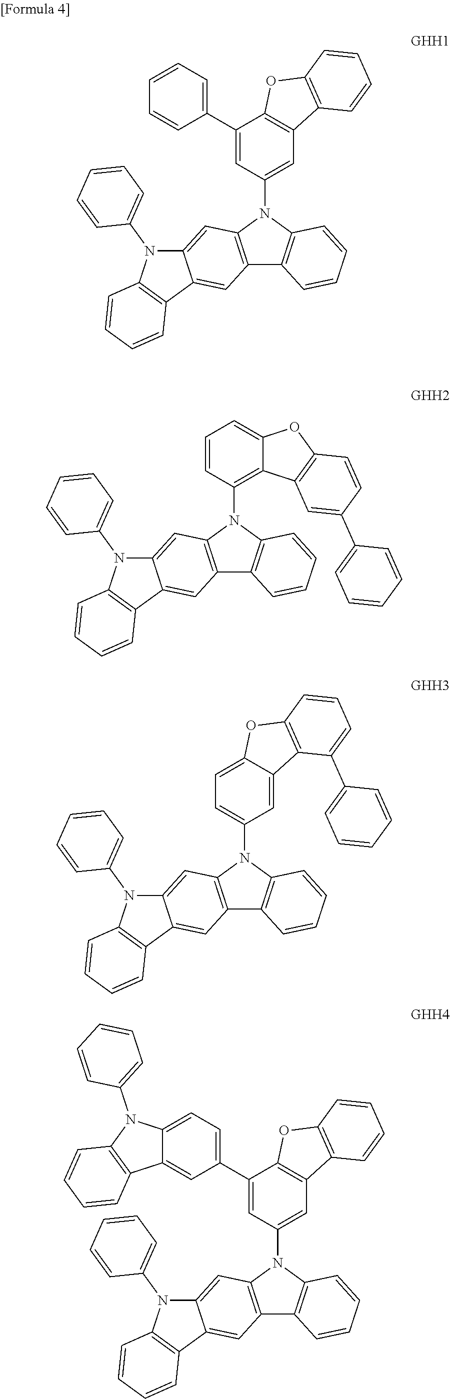

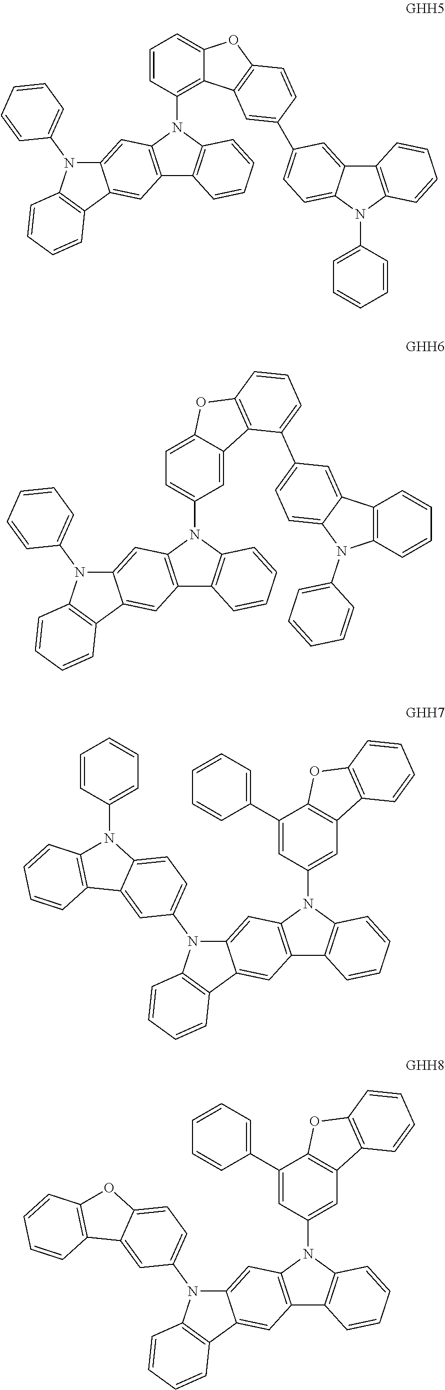 [SMILES: c1ccc(-n2c3ccccc3c3cc(-c4ccc5oc6cccc(-n7c8ccccc8c8cc9c%10ccccc%10n(-c%10ccccc%10)c9cc87)c6c5c4)ccc32)cc1 ; c1ccc(-n2c3ccccc3c3cc(-c4cccc5oc6ccc(-n7c8ccccc8c8cc9c%10ccccc%10n(-c%10ccccc%10)c9cc87)cc6c45)ccc32)cc1 ; c1ccc(-c2cc(-n3c4ccccc4c4cc5c6ccccc6n(-c6ccc7c(c6)c6ccccc6n7-c6ccccc6)c5cc43)cc3c2oc2ccccc23)cc1 ; c1ccc(-c2cc(-n3c4ccccc4c4cc5c6ccccc6n(-c6ccc7oc8ccccc8c7c6)c5cc43)cc3c2oc2ccccc23)cc1]

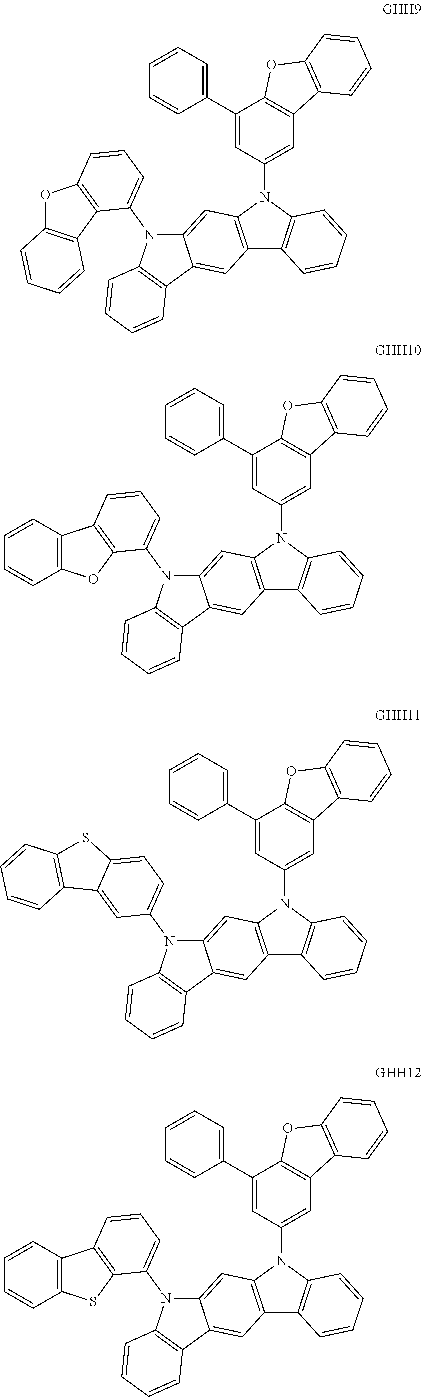 [SMILES: c1ccc(-c2cc(-n3c4ccccc4c4cc5c6ccccc6n(-c6cccc7oc8ccccc8c67)c5cc43)cc3c2oc2ccccc23)cc1 ; c1ccc(-c2cc(-n3c4ccccc4c4cc5c6ccccc6n(-c6cccc7c6oc6ccccc67)c5cc43)cc3c2oc2ccccc23)cc1 ; c1ccc(-c2cc(-n3c4ccccc4c4cc5c6ccccc6n(-c6ccc7sc8ccccc8c7c6)c5cc43)cc3c2oc2ccccc23)cc1 ; c1ccc(-c2cc(-n3c4ccccc4c4cc5c6ccccc6n(-c6cccc7c6sc6ccccc67)c5cc43)cc3c2oc2ccccc23)cc1]

The first n-type host can be a compound represented by Formula 5-1, and the green phosphorescent dopant can be a compound in Formula 5-2.

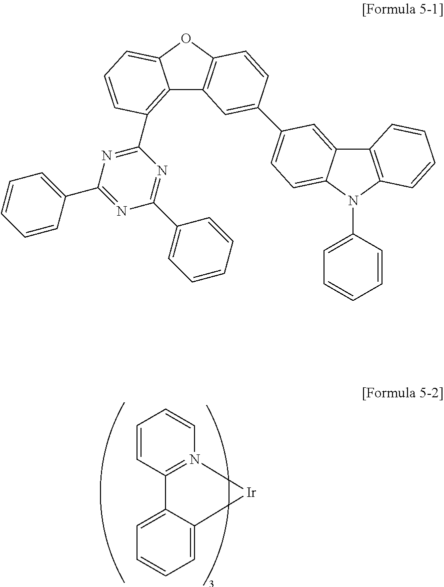

In an aspect of the present disclosure, the red EML 512 can include the second P-type host in Formula 2-1 and the second n-type host in Formula 2-2, and the green EML 514 can include the first p-type host in Formula 3 and the first n-type host in Formula 5-1. In this case, in the OLED D, the driving voltage is reduced, and the emitting efficiency is improved.

The third EML 510 can further include a yellow-green EML between the red and green EMLs 512 and 514.

The yellow-green EML can include a yellow-green host and a yellow-green dopant. For example, the yellow-green dopant can be a phosphorescent compound.

The yellow-green host can be selected from the materials for the green host.

The yellow-green dopant can be selected from the group consisting of 5,6,11,12-tetraphenylnaphthalene (Rubrene), 2,8-di-tert-butyl-5,11-bis(4-tert-butylphenyl)-6,12-diphenyltetracene (TBRb), bis(2-phenylbenzothiazolato)(acetylacetonate)irdium(III) (Ir(BT)₂(acac)), bis(2-(9,9-diethyl-fluoren-2-yl)-1-phenyl-1H-benzo[d]imdiazolato)(acetylacetonate)iridium(III) (Ir(fbi)₂(acac)), bis(2-phenylpyridine)(3-(pyridine-2-yl)-2H-chromen-2-onate)iridium(III) (fac-Ir(ppy)₂Pc), bis(2-(2,4-difluorophenyl)quinoline)(picolinate)iridium(III) (FPQIrpic), and bis(4-phenylthieno[3,2-c]pyridinato-N,C2′) (acetylacetonate) iridium(III) PO-01), but it is not limited thereto.

As described above, each of the first and second EMLs 310 and 410 is a blue EML, and the third EML 510 includes the red and green EMLs 512 and 514.

Namely, the OLED D of the present disclosure is an inverted-structure 3-stack white OLED.

The EIL 320 can include a matrix material and an n-type dopant. For example, the matrix material can be a compound represented by Formula 6 (4,7-dipheny-1,10-phenanthroline (Bphen)), and the n-type dopant can be an alkali metal, e.g., Li, Na, K or Cs, or an alkali earth metal, e.g., Mg, Sr, Ba or Ra.

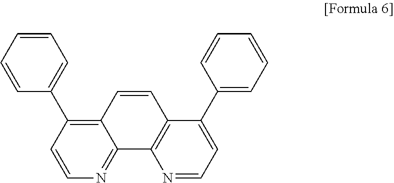 [SMILES: c1ccc(-c2ccnc3c2ccc2c(-c4ccccc4)ccnc23)cc1]

The EIL 320 can have a thickness of 100 to 200 Å. A weight % of the n-type dopant in the EIL 320 can be in a range of 3 to 7, e.g., 5.

The first ETL 330 contacts the EIL 320 and the first EML 310 and positioned between the EIL 320 and the first EML 310. The first ETL 330 can have a thickness of 800 to 1000 Å.

The first ETL 330 can include an electron transporting material including at least one of a compound in Formula 7-1, a compound in Formula 7-2 and a compound represented by Formula 8.

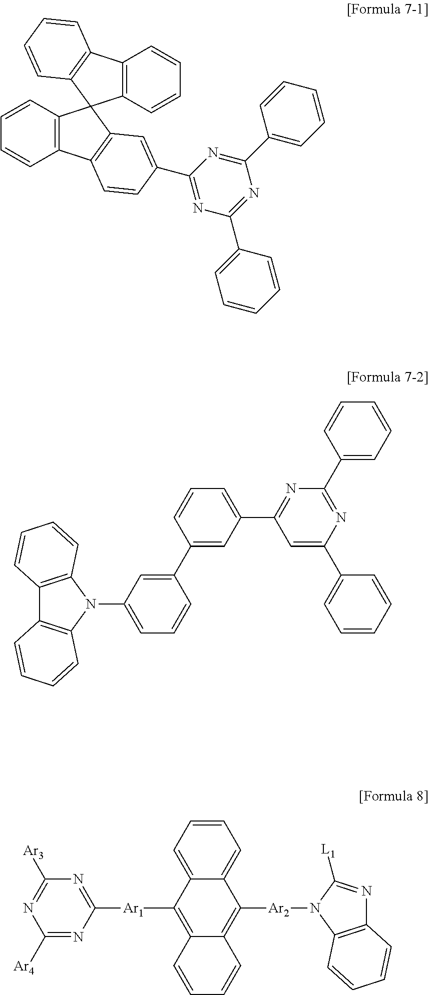

In Formula 8, each of Ar₁ and Ar₂ is independently selected from the group consisting of a single bond, a substituted or unsubstituted C6 to C30 arylene group and a substituted or unsubstituted C3 to C30 heteroarylene group,
each of Ar₃ and Ar₄ is independently selected from the group consisting of hydrogen, a substituted or unsubstituted C6 to C30 aryl group and a substituted or unsubstituted C3 to C30 heteroaryl group, and

L₁ is selected from the group consisting of a substituted or unsubstituted C1 to C10 alkyl group, a substituted or unsubstituted C3 to C30 cycloalkyl group, a substituted or unsubstituted C6 to C30 aryl group and a substituted or unsubstituted C3 to C30 heteroaryl group.

In Formula 8, each of Ar₁ and Ar₂ can be independently selected from the group consisting of a single bond and a substituted or unsubstituted C6 to C30 arylene group, e.g., 1,4-phenylene, 1,3-phenylene, 1,4-naphthylene or 2,6-naphthylene.

In Formula 8, each of Ar₃ and Ar₄ can be independently selected from the group consisting of a substituted or unsubstituted C6 to C30 aryl group, e.g., phenyl, biphenyl, 1-naphthyl or 2-naphthyl, and a substituted or unsubstituted C3 to C30 heteroaryl group, e.g., dibenzofuranyl or dibenzothiophenyl.

In Formula 8, L₁ can be selected from the group consisting of a substituted or unsubstituted C1 to C10 alkyl group, preferably C1 to C3 alkyl group, e.g., methyl or ethyl, and a substituted or unsubstituted C6 to C30 aryl group, e.g., phenyl, biphenyl, 1-naphthyl or 2-naphthyl.

For example, the electron transporting material represented by Formula 8 can be one of compounds in Formula 9.

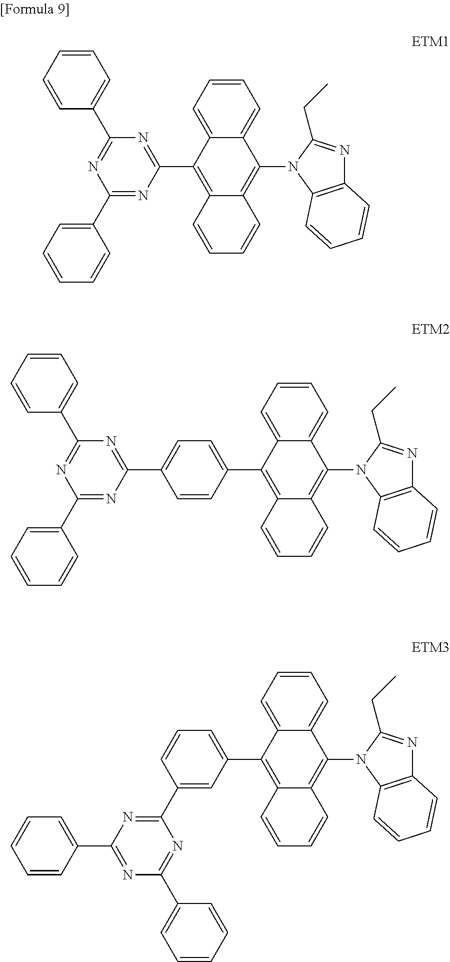 [SMILES: CCc1nc2ccccc2n1-c1c2ccccc2c(-c2nc(-c3ccccc3)nc(-c3ccccc3)n2)c2ccccc12 ; CCc1nc2ccccc2n1-c1c2ccccc2c(-c2ccc(-c3nc(-c4ccccc4)nc(-c4ccccc4)n3)cc2)c2ccccc12 ; CCc1nc2ccccc2n1-c1c2ccccc2c(-c2cccc(-c3nc(-c4ccccc4)nc(-c4ccccc4)n3)c2)c2ccccc12]

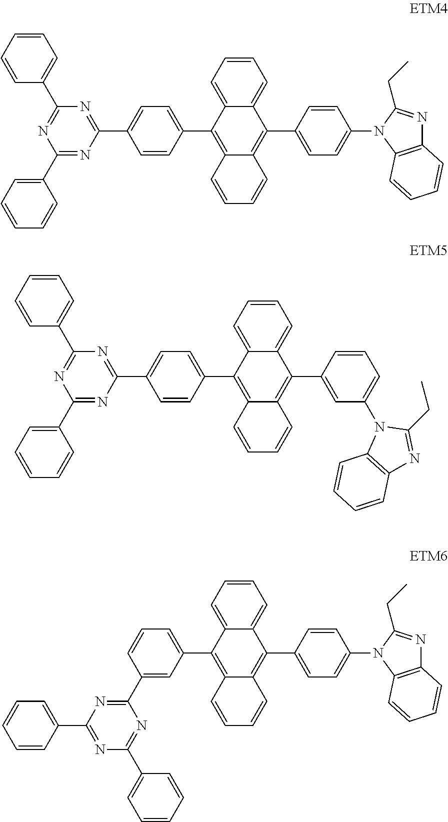 [SMILES: CCc1nc2ccccc2n1-c1ccc(-c2c3ccccc3c(-c3ccc(-c4nc(-c5ccccc5)nc(-c5ccccc5)n4)cc3)c3ccccc23)cc1 ; CCc1nc2ccccc2n1-c1cccc(-c2c3ccccc3c(-c3ccc(-c4nc(-c5ccccc5)nc(-c5ccccc5)n4)cc3)c3ccccc23)c1 ; CCc1nc2ccccc2n1-c1ccc(-c2c3ccccc3c(-c3cccc(-c4nc(-c5ccccc5)nc(-c5ccccc5)n4)c3)c3ccccc23)cc1]

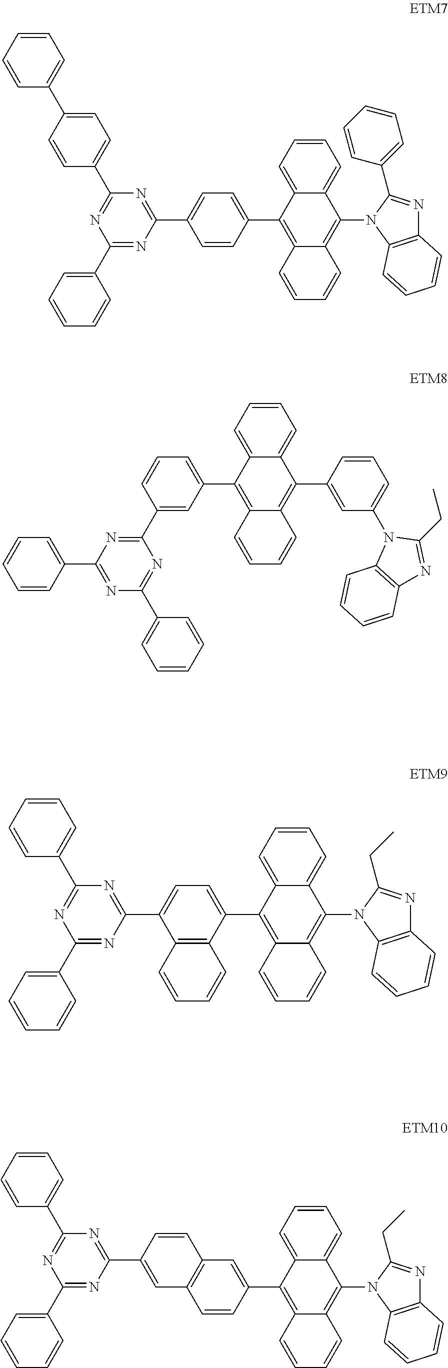 [SMILES: c1ccc(-c2ccc(-c3nc(-c4ccccc4)nc(-c4ccc(-c5c6ccccc6c(-n6c(-c7ccccc7)nc7ccccc76)c6ccccc56)cc4)n3)cc2)cc1 ; CCc1nc2ccccc2n1-c1cccc(-c2c3ccccc3c(-c3cccc(-c4nc(-c5ccccc5)nc(-c5ccccc5)n4)c3)c3ccccc23)c1 ; CCc1nc2ccccc2n1-c1c2ccccc2c(-c2ccc(-c3nc(-c4ccccc4)nc(-c4ccccc4)n3)c3ccccc23)c2ccccc12 ; CCc1nc2ccccc2n1-c1c2ccccc2c(-c2ccc3cc(-c4nc(-c5ccccc5)nc(-c5ccccc5)n4)ccc3c2)c2ccccc12]

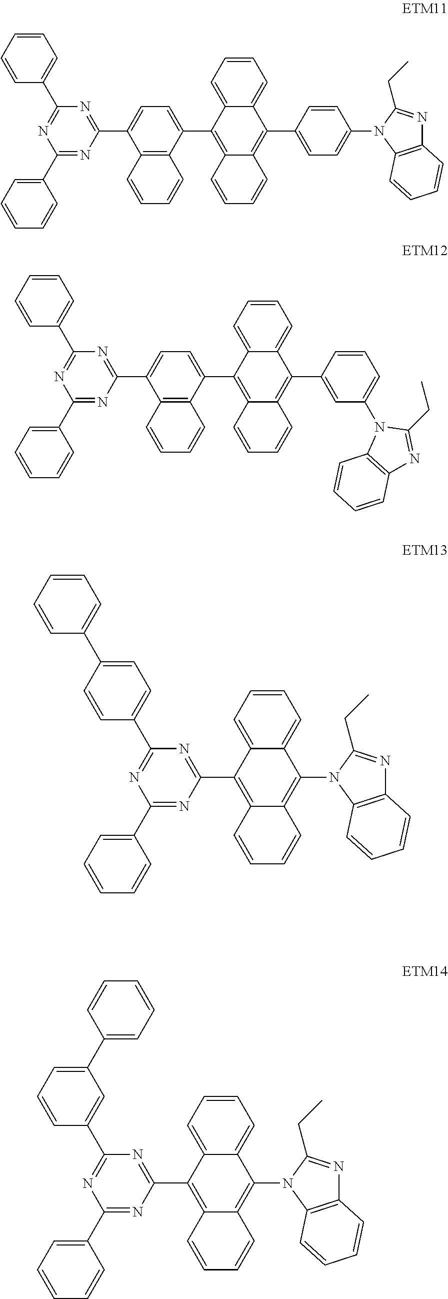 [SMILES: CCc1nc2ccccc2n1-c1ccc(-c2c3ccccc3c(-c3ccc(-c4nc(-c5ccccc5)nc(-c5ccccc5)n4)c4ccccc34)c3ccccc23)cc1 ; CCc1nc2ccccc2n1-c1cccc(-c2c3ccccc3c(-c3ccc(-c4nc(-c5ccccc5)nc(-c5ccccc5)n4)c4ccccc34)c3ccccc23)c1 ; CCc1nc2ccccc2n1-c1c2ccccc2c(-c2nc(-c3ccccc3)nc(-c3ccc(-c4ccccc4)cc3)n2)c2ccccc12 ; CCc1nc2ccccc2n1-c1c2ccccc2c(-c2nc(-c3ccccc3)nc(-c3cccc(-c4ccccc4)c3)n2)c2ccccc12]

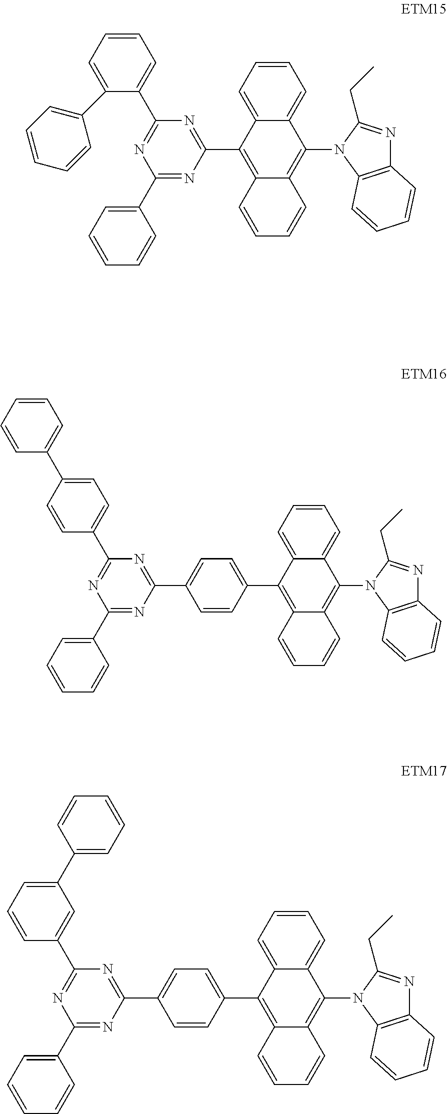 [SMILES: CCc1nc2ccccc2n1-c1c2ccccc2c(-c2nc(-c3ccccc3)nc(-c3ccccc3-c3ccccc3)n2)c2ccccc12 ; CCc1nc2ccccc2n1-c1c2ccccc2c(-c2ccc(-c3nc(-c4ccccc4)nc(-c4ccc(-c5ccccc5)cc4)n3)cc2)c2ccccc12 ; CCc1nc2ccccc2n1-c1c2ccccc2c(-c2ccc(-c3nc(-c4ccccc4)nc(-c4cccc(-c5ccccc5)c4)n3)cc2)c2ccccc12]

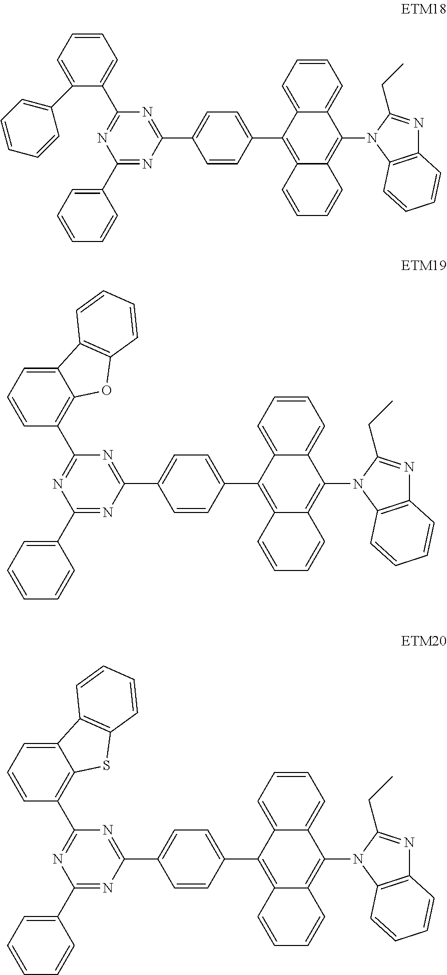 [SMILES: CCc1nc2ccccc2n1-c1c2ccccc2c(-c2ccc(-c3nc(-c4ccccc4)nc(-c4ccccc4-c4ccccc4)n3)cc2)c2ccccc12 ; CCc1nc2ccccc2n1-c1c2ccccc2c(-c2ccc(-c3nc(-c4ccccc4)nc(-c4cccc5c4oc4ccccc45)n3)cc2)c2ccccc12 ; CCc1nc2ccccc2n1-c1c2ccccc2c(-c2ccc(-c3nc(-c4ccccc4)nc(-c4cccc5c4sc4ccccc45)n3)cc2)c2ccccc12]

Namely, the first ETL 330 can include at least one of the compound in Formula 7-1, the compound in Formula 7-2 and the compounds in Formula 9.

In an aspect of the present disclosure, the first ETL 330 can include a lower layer 332 and an upper layer 334, and a thickness of the lower layer 332 can be greater than that of the upper layer 334. For example, the lower layer 332 can have a thickness of 750 to 850 Å, and the upper layer 334 can have a thickness of 50 to 150 Å. The lower layer 332 can include the compound in Formula 7-1, and the upper layer 334 can include the compound in Formula 7-2 or the compound represented by Formula 8.

The compound in Formula 7-2 has a triplet energy being higher than the compound in Formula 7-1. When the lower and upper layers 332 and 334 of the first ETL 330 respectively include the compound in Formula 7-1 and the compound in Formula 7-2, the driving voltage of the OLED D can be reduced, and the emitting efficiency of the OLED D can be improved.

The compound represented by Formula 8 has a triplet energy being higher than the compound in Formula 7-1 and an electron mobility being greater than the compound 7-2. When the lower and upper layers 332 and 334 of the first ETL 330 respectively include the compound in Formula 7-1 and the compound represented by Formula 8, the driving voltage of the OLED D can be further reduced.

In the above OLED D, the first EML 310 being a blue EML has a pre-determined distance from the cathode 210 being a transparent electrode to improve the emitting efficiency of the OLED D.

For example, the first ETL 330 has a thickness of about 800 to 1000 Å to provide a distance of 900 to 1200 Å between the first EML 310 and the cathode 210.

Namely, the OLED D of the present disclosure has an inverted-structure so that the aperture ratio of the organic light emitting display device 100 is improved, and the first ETL 330 has a relatively large thickness so that the emitting efficiency of the organic light emitting display device 100 is improved.

When the first ETL 330 has a relatively large thickness, the OLED has an improved emitting efficiency and significantly increased driving voltage.

However, in the present disclosure, the first ETL 330 includes at least one of the compound in Formula 7-1, the compound in Formula 7-2 and the compound represented by Formula 8, the increase of the driving voltage in the inverted-structure OLED can be minimized.

For example, when the first ETL 330 includes the lower layer 332 including the compound in Formula 7-1 and the upper layer 334 including the compound in Formula 9, the OLED D can have lower driving voltage with sufficiency emitting efficiency.

The first HTL 340 is positioned between the first EML 310 and the first CGL 600. The first HTL 340 can have a thickness of 70 to 150 Å and can include at least one of the a first hole transporting material and a second hole transporting material. The first hole transporting material can has a hole mobility of 1×10⁻³˜5×10⁻³ cm²V⁻¹s⁻¹ and a highest occupied molecular orbital (HOMO) of 5.5˜5.6 eV, and the second hole transporting material can has a hole mobility of 5×10⁻³˜5×10⁻⁴ cm²V⁻¹s⁻¹ and a HOMO of 5.6˜5.7 eV.

For example, the first hole transporting material can be a compound in Formula 10-1, and the second hole transporting material can be a compound in Formula 10-2.

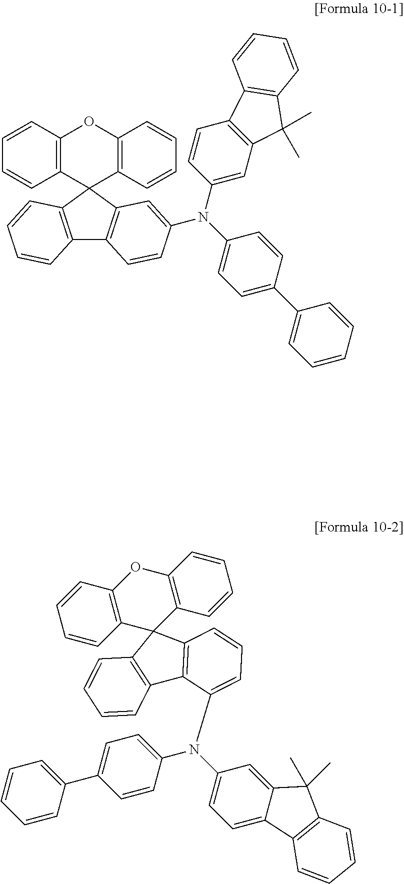 [SMILES: CC1(C)c2ccccc2-c2ccc(N(c3ccc(-c4ccccc4)cc3)c3ccc4c(c3)C3(c5ccccc5Oc5ccccc53)c3ccccc3-4)cc21 ; CC1(C)c2ccccc2-c2ccc(N(c3ccc(-c4ccccc4)cc3)c3cccc4c3-c3ccccc3C43c4ccccc4Oc4ccccc43)cc21]

In an aspect of the present disclosure, the first HTL 340 can include both the first hole transporting material in Formula 10-1 and the second hole transporting material in Formula 10-2. In this case, in the first HTL 340, a weight % of the first hole transporting material can be greater than a weight % of the second hole transporting material. For example, a ratio of a weight % of the first hole transporting material to a weight % of the second hole transporting material can be in a range of 8:2 to 6:4, preferably 7:3 to 6:4, more preferably 6:4. As a result, the driving voltage of the OLED D can be reduced.

The first EBL 350 contacts the first EML 310 and the first HTL 340 and is positioned between the first EML 310 and the first HTL 340. The first EBL 350 can have a thickness of 70 to 150 Å and can include an electron blocking material selected from the group consisting of tris(4-carbazoyl-9-yl-phenyl)amine (TCTA), tris[4-(diethylamino)phenyl]amine, N-(biphenyl-4-yl)-9,9-dimethyl-N-(4-(9-phenyl-9H-carbazol-3-yl)phenyl)-9H-fluoren-2-amine, TAPC, MTDATA, 1,3-bis(carbazol-9-yl)benzene (mCP), 3,3′-bis(N-carbazolyl)-1,1′-biphenyl (mCBP), copper phthalocyanine (CuPc), N,N′-bis[4-[bis(3-methylphenyl)amino]phenyl]-N,N′-diphenyl-[1,1′-biphenyl]-4,4′-diamine (DNTPD), 1,3,5-tris[4-(diphenylamino)phenyl]benzene (TDAPB), DCDPA, 2,8-bis(9-phenyl-9H-carbazol-3-yl)dibenzo[b,d]thiophene, and a compound in Formula 11.

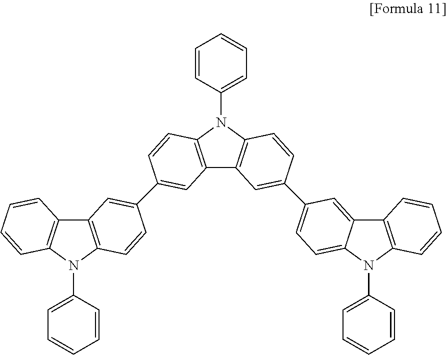 [SMILES: c1ccc(-n2c3ccccc3c3cc(-c4ccc5c(c4)c4cc(-c6ccc7c(c6)c6ccccc6n7-c6ccccc6)ccc4n5-c4ccccc4)ccc32)cc1]

The second ETL 420 contacts the second EML 410 and is positioned between the second EML 410 and the second CGL 630. The second ETL 420 can have a thickness of 400 to 500 Å. Namely, the second ETL 420 has a thickness being smaller than the first ETL 330.

The second ETL 420 can include an electron transporting material being at least one of the compound in Formula 7-1, the compound in Formula 7-2 and the compound represented by Formula 8. Namely, the second ETL 420 can include at least one of the compound in Formula 7-2, the compound in Formula 7-1 and the compounds in Formula 8. Alternatively, the second ETL 420 may include a compound in Formula 14.

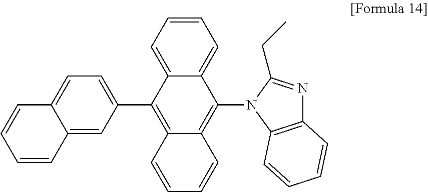 [SMILES: CCc1nc2ccccc2n1-c1c2ccccc2c(-c2ccc3ccccc3c2)c2ccccc12]

In an aspect of the present disclosure, the second ETL 420 can include a lower layer 422 and an upper layer 424, and a thickness of the lower layer 422 can be greater than that of the upper layer 424. For example, the lower layer 422 can have a thickness of 300 to 400 Å, and the upper layer 424 can have a thickness of 50 to 150 Å. The lower layer 422 can include the compound in Formula 7-1, and the upper layer 424 can include the compound in Formula 7-2 or the compound represented by Formula 8.

When the lower and upper layers 422 and 424 of the second ETL 420 respectively include the compound in Formula 7-1 and the compound in Formula 7-2, the driving voltage of the OLED D can be reduced, and the emitting efficiency of the OLED D can be improved.

When the lower and upper layers 422 and 424 of the second ETL 420 respectively include the compound in Formula 7-1 and the compound represented by Formula 8, the driving voltage of the OLED D can be further reduced.

The second HTL 430 can have a thickness of 70 to 150 Å and can include at least one of the a third hole transporting material and a fourth hole transporting material. The third hole transporting material can has a hole mobility of 4×10⁻⁵˜5×10⁻⁴ cm²V⁻¹s⁻¹ and a HOMO of 5.5˜5.6 eV, and the fourth hole transporting material can has a hole mobility of 1×10⁻⁴˜5×10⁻⁴ cm²V⁻¹s⁻¹ and a HOMO of 5.6˜5.7 eV.

For example, the third hole transporting material can be a compound in Formula 12-1, and the fourth hole transporting material can be a compound in Formula 12-2.

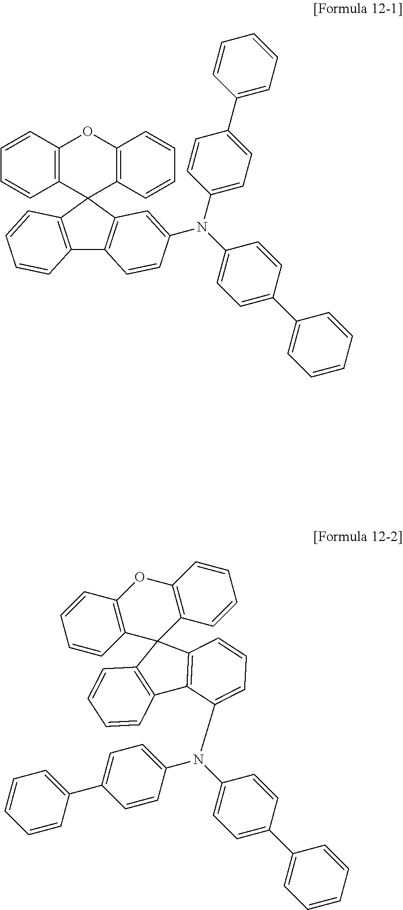 [SMILES: c1ccc(-c2ccc(N(c3ccc(-c4ccccc4)cc3)c3ccc4c(c3)C3(c5ccccc5Oc5ccccc53)c3ccccc3-4)cc2)cc1 ; c1ccc(-c2ccc(N(c3ccc(-c4ccccc4)cc3)c3cccc4c3-c3ccccc3C43c4ccccc4Oc4ccccc43)cc2)cc1]

In an aspect of the present disclosure, the second HTL 430 can include both the third hole transporting material in Formula 12-1 and the fourth hole transporting material in Formula 12-2. In this case, in the second HTL 430, a weight % of the third hole transporting material can be greater than a weight % of the fourth hole transporting material. For example, a ratio of a weight % of the third hole transporting material to a weight % of the fourth hole transporting material can be in a range of 8:2 to 6:4, preferably 6:4.

The HIL 440 is positioned between the second HTL 430 and the anode 230. The HIL 440 can have a thickness of 70 to 150 Å and can include a host and a p-type dopant.

In an aspect of the present disclosure, in the HIL 440, the host can be the first hole transporting material in Formula 10-1, and the p-type dopant can be a compound in Formula 13. In the HIL 440, a weight % of the p-type dopant can be in a range of 20 to 50, preferably 30 to 40.

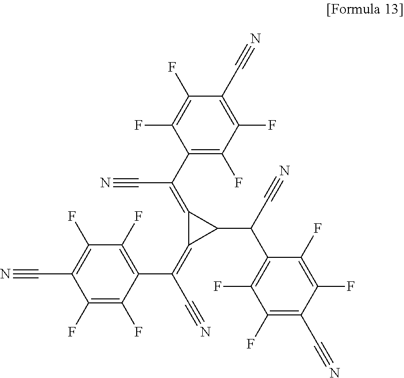 [SMILES: N#C/C(=C1\C(=C(\C#N)c2c(F)c(F)c(C#N)c(F)c2F)C1C(C#N)c1c(F)c(F)c(C#N)c(F)c1F)c1c(F)c(F)c(C#N)c(F)c1F]

With the second HTL 430 comprises the third hole transporting material according to Formula 12-1 and the fourth hole transporting material comprises a compound of Formula 12-2 and the HIL 440 including the host and the above p-type dopant as described above, the driving voltage of the OLED D can be reduced, and the emitting efficiency and the lifespan of the OLED D can be improved.

A p-dopant layer contacting the HIL 440 and the anode 230 can be disposed between the HIL 440 and the anode 230. In an aspect of the present disclosure, the p-dopant layer can have a thickness, e.g., 10 to 50A, being smaller than the HIL 440 and can be formed of the compound in Formula 13.

Namely, the HIL 440 including a hole transporting material and a p-type dopant and the p-dopant layer only including the p-type dopant can be sequentially stacked on the second HTL 430 and under the anode 230.

When the p-dopant layer is disposed between the HIL 440 and the anode 230, the driving voltage of the OLED D can be reduced, and the lifespan of the OLED D can be improved.

The second EBL 450 contacts the second EML 410 and the second HTL 430 and is positioned between the second EML 410 and the second HTL 430. The second EBL 450 can have a thickness of 70 to 150 Å and can include the above-mentioned electron blocking material.

The third ETL 520 can contact the red EML 512 and the first CGL 600 and can be positioned between the red EML 512 and the first CGL 600. The third ETL 520 can have a thickness of 70 to 150 Å. A thickness of the third EML 520 can be smaller than each of a thickness of the first ETL 330 and a thickness of the second ETL 420.

The third ETL 520 can include at least one of the compound in Formula 7-1, the compound in Formula 7-2 and the compound represented by Formula 8. Alternatively, the third ETL 520 can include a compound in Formula 14.

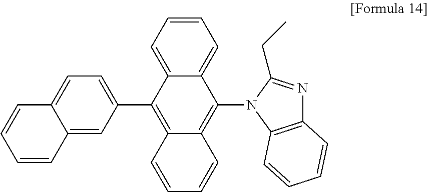 [SMILES: CCc1nc2ccccc2n1-c1c2ccccc2c(-c2ccc3ccccc3c2)c2ccccc12]

In an aspect of the present disclosure, the first ETL 330 can have a double-layered structure of the lower layer 332 including the compound in Formula 7-1 and the upper layer 334 including the compound in Formula 7-2 or the compound represented by Formula 8, the second ETL 420 can have a double-layered structure of the lower layer 422 including the compound in Formula 7-1 and the upper layer 424 including the compound in Formula 7-2 or the compound represented by Formula 8, and the third ETL 520 can have a single-layered structure of a layer including the compound in Formula 14.

The third HTL 530 can contact the green EML 514 and the second CGL 630 and can be positioned between the green EML 514 and the second CGL 630. The third HTL 530 can have a thickness of 40 Å to 500 Å, preferably 50 Å to 400 Å, preferably 100 Å to 300 Å, or preferably 150 Å to 250 Å. A thickness of the third HTL 530 can be greater than each of a thickness of the first HTL 340 and a thickness of the second HTL 430.

In an aspect of the present disclosure, a thickness of the third ETL 520 in the third emitting part 500 can be smaller than each of a thickness of the first ETL 330 in the first emitting part 300 and a thickness of the second ETL 420 in the second emitting part 400, while a thickness of the third HTL 530 in the third emitting part 500 can be greater than each of a thickness of the first HTL 340 in the first emitting part 300 and a thickness of the second HTL 430 in the second emitting part 400. In this case, the driving voltage of the OLED D can be reduced, and the emitting efficiency of the OLED D can be improved.

The third HTL 530 can include one of the compound in Formula 10-1, the compound in Formula 10-2, the compound in Formula 12-1 and the compound in Formula 12-2. In an aspect of the present disclosure, the third HTL 530 can include the compound in Formula 10-1.

The first CGL 600 contacts the first HTL 340 and the third ETL 520 and is positioned between the first HTL 340 and the third ETL 520. The first CGL 600 can include a first p-type CGL 610 and a first n-type CGL 620. The first p-type CGL 610 is positioned between the first HTL 340 and the third ETL 520, and the first n-type CGL 620 is positioned between the first p-type CGL 610 and the third ETL 520.

The first p-type CGL 610 provides a hole into the first EML 310 in the first emitting part 300, and the first n-type CGL 620 provides an electron into the third EML 510 in the third emitting part 500.

The second CGL 630 contacts the third HTL 530 and the second ETL 420 and is positioned between the third HTL 530 and the second ETL 420. The second CGL 630 can include a second p-type CGL 640 and a second n-type CGL 650. The second p-type CGL 640 is positioned between the third HTL 530 and the second ETL 420, and the second n-type CGL 650 is positioned between the second p-type CGL 640 and the second ETL 420.

The second p-type CGL 640 provides a hole into the third EML 510 in the third emitting part 500, and the second n-type CGL 650 provides an electron into the second EML 410 in the second emitting part 400.

Each of the first p-type CGL 610, the first n-type CGL 620 and the second p-type CGL 640 can have a thickness of 70 to 150 Å, and the second n-type CGL 650 can have a thickness of 150 to 250 Å. Namely, each of the first p-type CGL 610, the first n-type CGL 620 and the second p-type CGL 640 can have substantially the same thickness, and the second n-type CGL 650 can have a thickness being greater than each of the first p-type CGL 610, the first n-type CGL 620 and the second p-type CGL 640.

Each of the first p-type CGL 610 and the second p-type CGL 640 can include a host and a p-type dopant, and each of the first n-type CGL 620 and the second n-type CGL 650 can include a host and a n-type dopant. The p-type dopant in each of the first and second p-type CGLs 610 and 640 can have a weight % of 5 to 10, and the n-type dopant in each of the first and second n-type CGLs 620 and 650 can have a weight % of 0.5 to 3.

In an aspect of the present disclosure, the host in the first p-type CGL 610 can be the compound in Formula 10-1, and the host in the second p-type CGL 640 can be the compound in Formula 10-2. The p-type dopant in each of the first and second p-type CGLs 610 and 640 can be the compound in Formula 13.

In each of the first and second n-type CGLs 620 and 650, the host can be the compound in Formula 6, and the n-type dopant can be alkali metal, e.g., Li, Na, K or Cs, or alkali earth metal, e.g., Mg, Sr, Ba or Ra.

In the above OLED D, the first ETL 330 has a relatively large thickness so that the first EML 310 being a blue EML has a pre-determined distance from the cathode 210. As a result, the emitting efficiency of the OLED D can be improved.

In addition, since the first ETL 330 has the first thickness and includes the lower layer 332 including the compound in Formula 7-1 and the upper layer 334 including the compound in Formula 7-2 or the compound represented by Formula 8, the driving voltage of the OLED D can be reduced, and the emitting efficiency of the OLED D can be improved.

Since the first HTL 340 includes the compound in Formula 10-1 and the compound in Formula 10-2, the driving voltage of the OLED D can be reduced.

Since the second ETL 420 has the second thickness and includes the lower layer 422 including the compound in Formula 7-1 and the upper layer 424 including the compound in Formula 7-2 or the compound represented by Formula 8, the driving voltage of the OLED D can be reduced, and the emitting efficiency of the OLED D can be improved.

The second HTL 430 includes the compound in Formula 12-1 and the compound in Formula 12-2, and a weight % of the compound in Formula 12-1 is greater than that of the compound in Formula 12-2. As a result, the driving voltage of the OLED D can be reduced.

The HIL 440 includes the compound in Formula 10-1 and the p-type dopant in Formula 13. As a result, the driving voltage of the OLED D can be reduced, and the emitting efficiency of the OLED D can be improved.

When the p-dopant layer, which is formed of the p-type dopant in Formula 13, is disposed between the HIL 440 and the anode 230, the driving voltage of the OLED D can be reduced, and the lifespan of the OLED D can be improved.

The green EML 514 includes the p-type host represented by Formula 3. As a result, the driving voltage of the OLED D can be reduced, and the emitting efficiency of the OLED D can be improved.

### EXAMPLES

The following examples are exemplary and not intended to be limiting. The above disclosure provides many different embodiments for implementing the features of the invention, and the following examples describe certain embodiments. It will be appreciated that other modifications and methods known to one of ordinary skill in the art can also be applied to the following experimental procedures, without departing from the scope of the invention.

### Synthesis of the Second p-Type Host

### 1. Synthesis of the Compound GHH1

### (1) Compound A

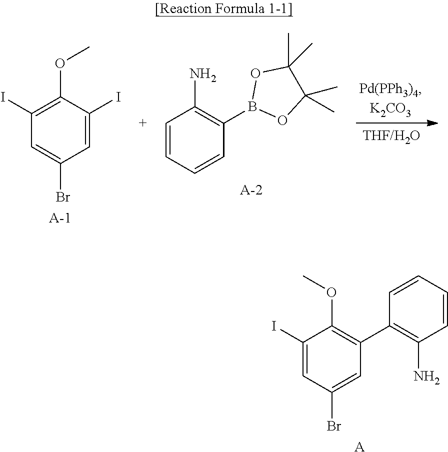

In the round-bottom 3-neck flask (1000 mL), the compound A-1 (44.9 g, 0.103 mol), the compound A-2 (10 g, 0.034 mol), potassium carbonate (37.8 g, 0.205 mol) and Pd(PPh₃)₄ (2.6 g, 0.002 mol) were dissolved in THF (450 mL). The degassed H₂O (150 mL) were injected, and the mixture was inert-refluxed and stirred for 12 hours. After completion of reaction, the mixture was extracted using diethyl ether and dried using magnesium sulfate. By extracting the solvent and performing a column-chromatography using a mixed solution of dichloromethane and hexane as an eluent, the compound A was obtained. (7 g, 51%).

### (2) Compound B

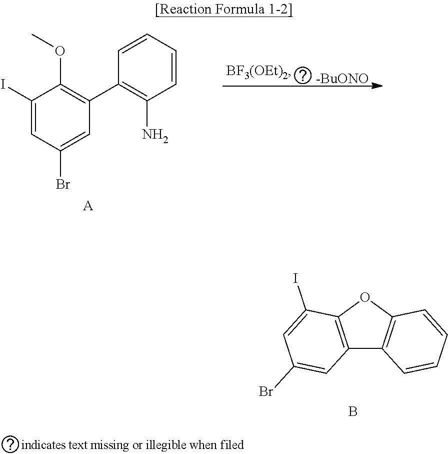

In the round-bottom 3-neck flask (250 mL), the compound A (20 g, 0.050 mol) and BF₃(Oet)₂ (10.5 g, 0.074 mol) were dissolved in a solvent of o-dichlorobenzene (100 mL), and the mixture was stirred at the room temperature for 1 hour. After the mixture was cooled into 0° C., tert-butyl nitrite (6.7 g, 0.065 mol) was added into the mixture. Tert-butyl nitrite was injected into the mixture, and the mixture was stirred at 105° C. for 12 hours. After the mixture was washed with water and dried with magnesium sulfate, the solvent was evaporated. By performing a column-chromatography using hexane as an eluent, the compound B was obtained. (15 g, 81%).

### (3) Compound C

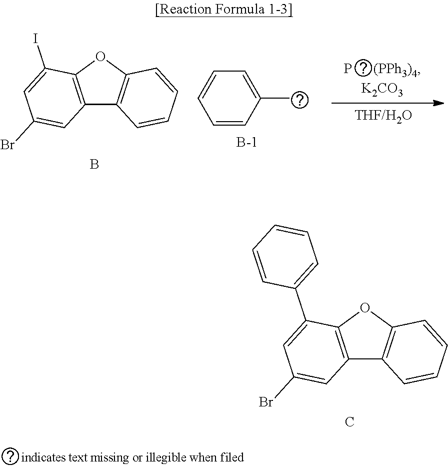

In the round-bottom 3-neck flask (500 mL), the compound B (16 g, 0.043 mol), the compound B-1 (2.63 g, 0.022 mol), potassium carbonate (17.8 g, 0.129 mol) and Pd(PPh₃)₄ (1.24 g, 0.050 mol) were dissolved in THF (150 mL). The degassed H₂O (30 mL) were injected, and the mixture was inert-refluxed and stirred for 12 hours. After completion of reaction, the mixture was extracted using diethyl ether and dried using magnesium sulfate. By extracting the solvent and performing a column-chromatography using a mixed solution of dichloromethane and hexane as an eluent, the compound C was obtained. (6 g, 87%).

### (4) Compound GHH1

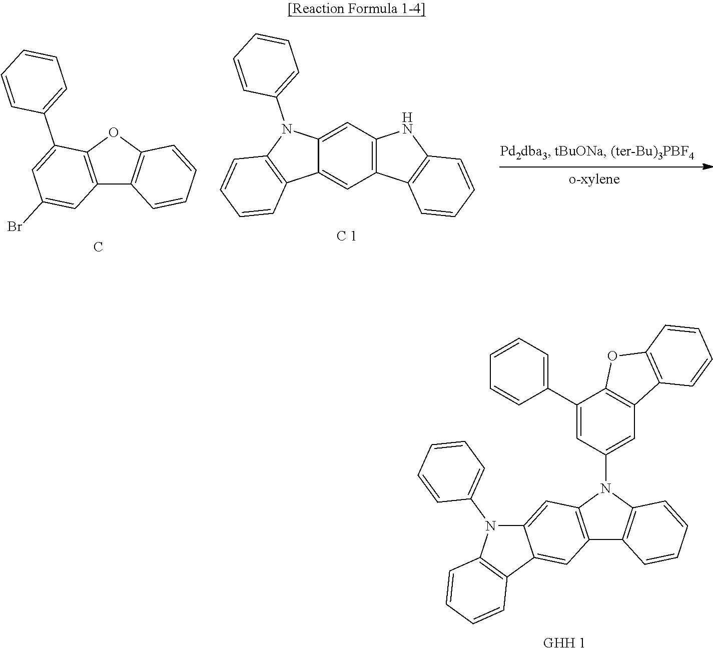

In the round-bottom 3-neck flask (250 mL), the compound C (6 g, 0.019 mol), the compound C-1 (5.6 g, 0.022 mol), tert-sodium butoxide (2.44 g, 0.025 mol), Pd₂(dba)₃ (0.78 g, 0.001 mol), tri-tert butyl phosphonium tetrafluoroborate (0.74 g, 0.003 mol) and o-xylene (100 mL) were inert-refluxed and stirred for 24 hours. After completion of reaction, the mixture was dried and filtered, and the solvent was evaporated. By performing a column-chromatography using a mixed solution of dichloromethane and hexane as an eluent, the compound GHH1 was obtained. (7 g, 72%).

### [OLED1]

A cathode (ITO, 1100 Å), an EIL (the compound in Formula 6 and L₁ (5 wt %), 150 Å), a first ETL (930 Å), a first blue EML (the compound in Formula 1-1 and the compound in Formula 1-2 (1.8 wt %), 200 Å), a first EBL (the compound in Formula 11, 100 Å), a first HTL (the compound in Formula 10-1 and the compound in Formula 10-2 (a weight % ratio=8:2), 100 Å), a first p-type CGL (the compound in Formula 10-1 and the compound in Formula 13 (10 wt %), 100 Å), a first n-type CGL (the compound in Formula 6 and Li (1.5 wt %), 100 Å), a third ETL (the compound in Formula 14, 100 Å), a red EML (130 Å), a green EML (305 Å), a third HTL (the compound in Formula 10-1 and the compound in Formula 10-2, 450 Å), a second p-type CGL (the compound in Formula 10-2 and the compound in Formula 13 (10 wt %), 100 Å), a second n-type CGL (the compound in Formula 6 and Li (1.5 wt %), 200 Å), a second ETL (the compound in Formula 14, 440 Å), a second blue EML (the compound in Formula 1-1 and the compound in Formula 1-2 (1.8 wt %), 300 Å), a second EBL (the compound in Formula 11, 100 Å), a second HTL (the compound in Formula 12-1 and the compound in Formula 12-2 (a weight % ratio=6:4), 100 Å), an HIL (the compound in Formula 10-1 and the compound in Formula 13 (20 wt %), 100 Å), and an anode (Al, 1000 Å) were sequentially stacked on a substrate to form an inverted-structure 3-stack white OLED.

The red EML was formed by using the compound in Formula 2-1 as a p-type host, a compound in Formula 15 as an n-type host and the compound in Formula 2-3 as a red dopant with 3.5 wt %, and the green EML was formed by using a compound in Formula 16 as a p-type host, the compound in Formula 5-1 as an n-type host and the compound in Formula 5-2 as a green dopant with 10 wt %.

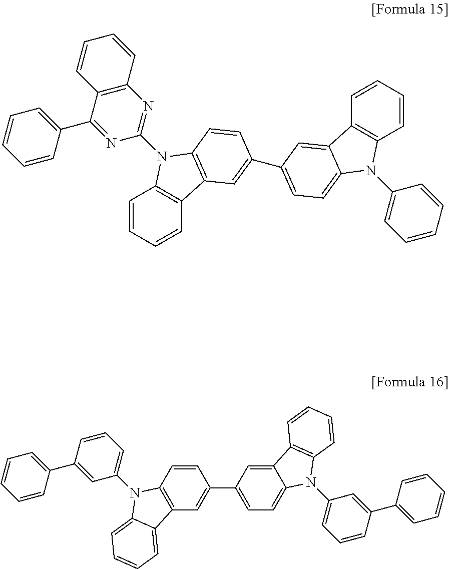 [SMILES: c1ccc(-c2nc(-n3c4ccccc4c4cc(-c5ccc6c(c5)c5ccccc5n6-c5ccccc5)ccc43)nc3ccccc23)cc1 ; c1ccc(-c2cccc(-n3c4ccccc4c4cc(-c5ccc6c(c5)c5ccccc5n6-c5cccc(-c6ccccc6)c5)ccc43)c2)cc1]

### 1. Comparative Example 1 (Ref1)

The compound in Formula 14 was used to form the first ETL of a single-layered structure.

### 2. Example

### (1) Example 1 (Ex1)

The compound in Formula 7-1 was used to form the first ETL of a single-layered structure.

### (2) Example 2 (Ex2)

The compound in Formula 7-1 was used to form a lower layer (830 Å) of the first ETL having a double-layered structure, and the compound in Formula 7-2 was used to form an upper layer (100 Å) of the first ETL having a double-layered structure.

### (3) Example 3 (Ex3)

The compound in Formula 7-1 was used to form a lower layer (830 Å) of the first ETL having a double-layered structure, and the compound ETM2 in Formula 9 was used to form an upper layer (100 Å) of the first ETL having a double-layered structure.

The emission properties, e.g., driving voltages (V1 and V2), an efficiency (cd/A), an external quantum efficiency (EQE), a blue index (BI) and a color coordinate index (CIE(I, y)), of the OLED of Comparative Example 1 and Examples 1 to 3 were measured and listed in Table 1. In Table 1, the driving voltage “V1” is a value measured at 10 mA/cm², and the driving voltage “V2” is a value measured at 100 mA/cm².

TABLE 1

| | V1 | V2 | cd/A | EQE | BI | Bx | By |
|---|---|---|---|---|---|---|---|
| Ref1 | 100% | 100% | 100% | 100% | 100% | — | — |
| Ex1 | 73% | 73% | 100% | 101% | 100% | 0.000 | 0.000 |
| Ex2 | 71% | 72% | 113% | 113% | 111% | 0.000 | 0.001 |
| Ex3 | 65% | 61% | 98% | 99% | 98% | −0.001 | 0.000 |

As shown in Table 1, in comparison to the OLED of Comparative Example 1, where the first ETL includes the compound in Formula 14, the OLED of Examples 1 to 3, where the first ETL includes at least one of the compounds in Formula 7-1, 7-2 and 9, has advantages in at least one of the driving voltage and the emitting efficiency.

For example, in the OLED of Example 3, where the first ETL has a double-layered structure of the lower layer including the compound in Formula 7-1 and the upper layer including the compound in Formula 9, the increase of the driving voltage, which is a disadvantage of an inverted-structure OLED, can be minimized with sufficient emitting efficiency.

### [OLED2]

A cathode (ITO, 1100 Å), an EIL (the compound in Formula 6 and L₁ (5 wt %), 150 Å), a first ETL (a lower layer (the compound in Formula 7-1, 830 Å) and an upper layer (the compound in Formula 7-2, 100 Å), a first blue EML (the compound in Formula 1-1 and the compound in Formula 1-2 (1.8 wt %), 200 Å), a first EBL (the compound in Formula 11, 100 Å), a first HTL (the compound in Formula 10-1 and the compound in Formula 10-2, 100 Å), a first p-type CGL (the compound in Formula 10-1 and the compound in Formula 13 (10 wt %), 100 Å), a first n-type CGL (the compound in Formula 6 and L₁ (1.5 wt %), 100 Å), a third ETL (the compound in Formula 14, 100 Å), a red EML (130 Å), a green EML (305 Å), a third HTL (the compound in Formula 10-1 and the compound in Formula 10-2, 450 Å), a second p-type CGL (the compound in Formula 10-2 and the compound in Formula 13 (10 wt %), 100 Å), a second n-type CGL (the compound in Formula 6 and Li (1.5 wt %), 200 Å), a second ETL (the compound in Formula 14, 440 Å), a second blue EML (the compound in Formula 1-1 and the compound in Formula 1-2 (1.8 wt %), 300 Å), a second EBL (the compound in Formula 11, 100 Å), a second HTL (the compound in Formula 12-1 and the compound in Formula 12-2 (a weight % ratio=6:4), 100 Å), an HIL (the compound in Formula 10-1 and the compound in Formula 13 (20 wt %), 100 Å), and an anode (Al, 1000 Å) were sequentially stacked on a substrate to form an inverted-structure 3-stack white OLED.

The red EML was formed by using the compound in Formula 2-1 as a p-type host, the compound in Formula 15 as an n-type host and the compound in Formula 2-3 as a red dopant with 3.5 wt %, and the green EML was formed by using the compound in Formula 16 as a p-type host, the compound in Formula 5-1 as an n-type host and the compound in Formula 5-2 as a green dopant with 10 wt %.

### 3. Example

### (1) Example 4 (Ex4)

The compound in Formula 10-1 (70 wt %) and the compound in Formula 10-2 (30 wt %) was used to form the first HTL.

### (2) Example 5 (Ex5)

The compound in Formula 10-1 (60 wt %) and the compound in Formula 10-2 (40 wt %) was used to form the first HTL.

The emission properties, e.g., driving voltages (V1 and V2), an efficiency (cd/A), an external quantum efficiency (EQE), a blue index (BI), a color coordinate index (CIE(I, y)) and a lifespan (LT), of the OLED of Examples 2, 4 and 5 were measured and listed in Table 2. In Table 2, the driving voltage “V1” is a value measured at 10 mA/cm², and the driving voltage “V2” is a value measured at 100 mA/cm².

TABLE 2

| | V1 | V2 | cd/A | EQE | BI | Bx | By | LT |
|---|---|---|---|---|---|---|---|---|
| Ex2 | 100% | 100% | 100% | 100% | 100% | — | — | 100% |
| Ex4 | 97% | 95% | 97% | 99% | 99% | 0.000 | −0.001 | 100% |
| Ex5 | 96% | 93% | 95% | 96% | 96% | 0.000 | −0.001 | 100% |

As shown in Table 2, in comparison to the OLED of Example 2, where a weight % of the first hole transporting material, i.e., the compound in Formula 10-1, having a relatively high hole mobility is relative large, the driving voltage of the OLED of Examples 4 and 5, where a weight % of the second hole transporting material, i.e., the compound in Formula 10-2, having a relatively low hole mobility is increased to be 30 to 40 wt %, is further reduced.

### [OLED3]

### 4. Example

### (1) Example 6 (Ex6)

In the OLED of Example 2, the compound in Formula 7-1 was used to form a lower layer (830 Å) of the second ETL having a double-layered structure, and the compound in Formula 7-2 was used to form an upper layer (100 Å) of the second ETL having a double-layered structure.

### (2) Example 7 (Ex7)

In the OLED of Example 3, the compound in Formula 7-1 was used to form a lower layer (830 Å) of the second ETL having a double-layered structure, and the compound ETM2 in Formula 9 was used to form an upper layer (100 Å) of the second ETL having a double-layered structure.

The emission properties, e.g., driving voltages (V1 and V2), an efficiency (cd/A), an external quantum efficiency (EQE), a blue index (BI), a color coordinate index (CIE(I, y)) and a lifespan (LT), of the OLED of Examples 6 and 7 were measured and listed in Table 3. In Table 3, the driving voltage “V1” is a value measured at 10 mA/cm², and the driving voltage “V2” is a value measured at 100 mA/cm².

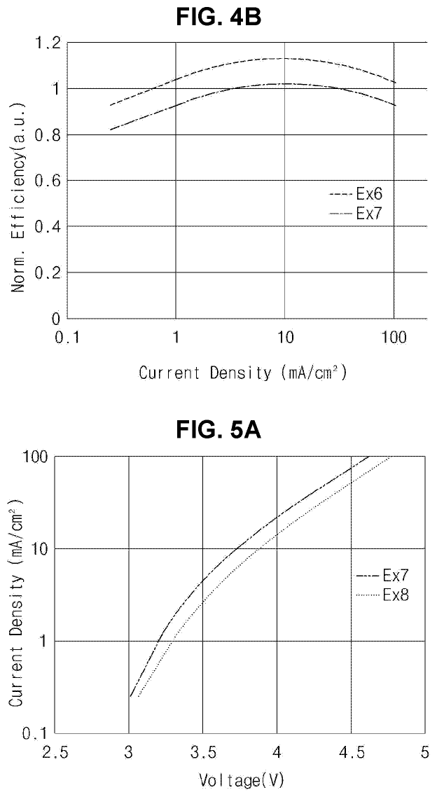

In addition, a current density according to a voltage in an OLED is shown by FIG. 4A, and an emitting efficiency according to a current density in an OLED is shown by FIG. 4B.

TABLE 3

| | V1 | V2 | cd/A | EQE | BI | Bx | By | LT |
|---|---|---|---|---|---|---|---|---|
| Ex6 | 100% | 100% | 100% | 100% | 100% | 0.002 | −0.011 | 100% |
| Ex7 | 96% | 92% | 96% | 90% | 88% | 0.001 | −0.004 | 116% |

As shown in Table 3, the OLED of Example 7, in which the second ETL has a double-layered structure including a lower layer of the compound in Formula 7-1 and an upper layer of the compound in Formula 9 provides low driving voltage and improved lifespan with sufficient emitting efficiency.

### [OLED4]

### 5. Example

### (1) Example 8 (Ex8)

In the OLED of Example 7, the second HTL was formed by using the compound in Formula 12-1 (40 wt %) and the compound in Formula 12-2 (60 wt %).

The emission properties, e.g., driving voltages (V1 and V2), an efficiency (cd/A), an external quantum efficiency (EQE), a blue index (BI), a color coordinate index (CIE(I, y)) and a lifespan (LT), of the OLED of Examples 7 and 8 were measured and listed in Table 4. In Table 4, the driving voltage “V1” is a value measured at 10 mA/cm², and the driving voltage “V2” is a value measured at 100 mA/cm².

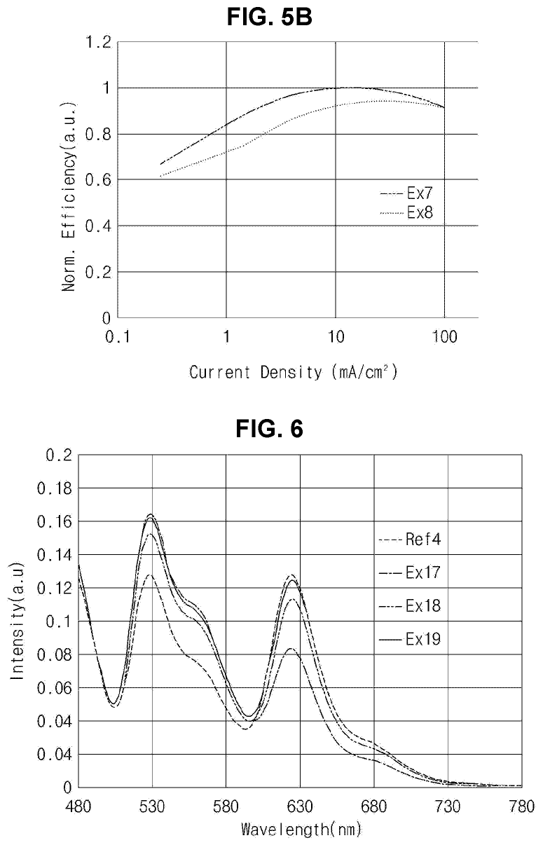

In addition, a current density according to a voltage in an OLED is shown by FIG. 5A, and an emitting efficiency according to a current density in an OLED is shown by FIG. 5B.

TABLE 4

| | V1 | V2 | cd/A | EQE | BI | Bx | By | LT |
|---|---|---|---|---|---|---|---|---|
| Ex7 | 100% | 100% | 100% | 100% | 100% | — | — | 100% |
| Ex8 | 104% | 103% | 92% | 93% | 94% | 0.000 | −0.001 | 83% |

As shown in Table 4, when a weight % of the fourth hole transporting material is greater than a weight % of the third hole transporting material in the second HTL, the driving voltage of the OLED is increased, and the emitting efficiency and the lifespan of the OLED are decreased. In other words, when a weight % of the third hole transporting material is greater than a weight % of the fourth hole transporting material in the second HTL, the driving voltage of the OLED is decreased, and the emitting efficiency and the lifespan of the OLED are increased.

### [OLED5]

### 6. Example

### (1) Example 9 (Ex9)

In the OLED of Example 6, the HIL was formed by using the compound in Formula 10-1 (70 wt %) and the compound in Formula 13 (30 wt %).

### (2) Example 10 (Ex10)

In the OLED of Example 6, the HIL was formed by using the compound in Formula 10-1 (60 wt %) and the compound in Formula 13 (40 wt %).

### (3) Example 11 (Ex11)

In the OLED of Example 6, the HIL was formed by using the compound in Formula 10-1 (50 wt %) and the compound in Formula 13 (50 wt %).

### 7. Comparative Example

### (1) Comparative Example 2 (Ref2)

In the OLED of Example 6, the HIL was formed by using HATCN instead of the compound in Formula 10-1 and the compound in Formula 13.

### (2) Comparative Example 3 (Ref3)

In the OLED of Example 6, the HIL was formed by using the compound in Formula 13 without the compound in Formula 10-1.

The emission properties, e.g., driving voltages (V1 and V2), an efficiency (cd/A), an external quantum efficiency (EQE), a blue index (BI), a color coordinate index (CIE(I, y)) and a lifespan (LT), of the OLED of Examples 6 and 9 to 11 and Comparative Examples 2 and 3 were measured and listed in Table 5. In Table 5, the driving voltage “V1” is a value measured at 10 mA/cm², and the driving voltage “V2” is a value measured at 100 mA/cm².

TABLE 5

| | V1 | V2 | cd/A | EQE | BI | Bx | By | LT |
|---|---|---|---|---|---|---|---|---|
| Ex6 | 100% | 100% | 100% | 100% | 100% | — | — | 100% |
| Ex9 | 97% | 96% | 99% | 100% | 100% | 0.000 | −0.001 | 100% |
| Ex10 | 97% | 96% | 98% | 100% | 100% | 0.000 | −0.001 | 92% |
| Ex11 | 96% | 95% | 97% | 97% | 97% | 0.000 | 0.000 | 85% |
| Ref2 | 109% | 112% | 20% | 27% | 28% | 0.003 | −0.021 | 0% |
| Ref3 | 111% | 118% | 36% | 48% | 50% | 0.003 | −0.021 | 0% |

As shown in Table 5, in the OLED of Comparative Examples 2 and 3, in which the HIL is formed by a p-type dopant material, i.e., HATCN or the compound in Formula 13, without a host material, i.e., a hole transporting material, the driving voltage is significantly increased, and the emitting efficiency is significantly decreased. In addition, in the OLED of Comparative Examples 2 and 3, the lifespan is decreased to a point below detection.

On the other hand, the OLED of Examples 6 and 9 to 11, in which the HIL includes the compound in Formula 10-1 and the compound in Formula 13 has low driving voltage and sufficiency emitting efficiency and lifespan.

### [OLED6]

### 8. Example

### (1) Example 12 (Ex12)

In the OLED of Example 6, a p-type dopant layer (10 Å) formed of the compound in Formula 13 was further formed between the HIL and the anode.

### (2) Example 13 (Ex13)

In the OLED of Example 6, a p-type dopant layer (30 Å) formed of the compound in Formula 13 was further formed between the HIL and the anode.

### (3) Example 14 (Ex14)

In the OLED of Example 6, a p-type dopant layer (50 Å) formed of the compound in Formula 13 was further formed between the HIL and the anode.

The emission properties, e.g., driving voltages (V1 and V2), an efficiency (cd/A), an external quantum efficiency (EQE), a blue index (BI), a color coordinate index (CIE(I, y)) and a lifespan (LT), of the OLED of Examples 6 and 12 to 14 were measured and listed in Table 6. In Table 6, the driving voltage “V1” is a value measured at 10 mA/cm², and the driving voltage “V2” is a value measured at 100 mA/cm².

TABLE 6

| | V1 | V2 | cd/A | EQE | BI | Bx | By | LT |
|---|---|---|---|---|---|---|---|---|
| Ex6 | 100% | 100% | 100% | 100% | 100% | — | — | 100% |
| Ex12 | 97% | 96% | 98% | 97% | 97% | 0.000 | 0.001 | 102% |
| Ex13 | 95% | 94% | 96% | 96% | 96% | 0.000 | 0.000 | 109% |
| Ex14 | 95% | 92% | 95% | 91% | 91% | −0.001 | 0.003 | 125% |

As shown in Table 6, in the OLED further including the p-type dopant layer, the driving voltage is further decreased, and the lifespan is further increased. For example, the p-dopant layer can have a thickness of 30 to 50 Å.

### [OLED7]

### 9. Example

### (1) Example 15 (Ex15)

In the OLED of Example 2, the EIL was formed by using the compound in Formula 6 and Li (3 wt %).

### (2) Example 16 (Ex16)

In the OLED of Example 2, the EIL was formed by using the compound in Formula 6 and Li (2 wt %).

The emission properties, e.g., driving voltages (V1 and V2), an efficiency (cd/A), an external quantum efficiency (EQE), a blue index (BI), a color coordinate index (CIE(x, y)) and a lifespan (LT), of the OLED of Examples 2, 15 and 16 were measured and listed in Table 7. In Table 7, the driving voltage “V1” is a value measured at 10 mA/cm², and the driving voltage “V2” is a value measured at 100 mA/cm².

TABLE 7

| | V1 | V2 | cd/A | EQE | BI | Bx | By | LT |
|---|---|---|---|---|---|---|---|---|
| Ex2 | 100% | 100% | 100% | 100% | 100% | — | — | 100% |
| Ex15 | 101% | 102% | 105% | 105% | 105% | 0.000 | 0.000 | 93% |
| Ex16 | 102% | 104% | 106% | 106% | 105% | 0.000 | 0.000 | 86% |

As shown in Table 7, as a weight % of the n-type dopant, i.e., Li, in the EIL is decreased, the driving voltage is increased, and the lifespan is decreased. Accordingly, a weight % of the n-type dopant in the EIL can be greater than each of a weight % of the n-type dopant in the first n-type CGL and a weight % of the n-type dopant in the second n-type CGL.

### [OLED8]

A cathode (ITO, 1100 Å), an EIL (the compound in Formula 6 and Li (5 wt %), 150 Å), a first ETL (a lower layer (the compound in Formula 7-1, 830 Å) and an upper layer (the compound in Formula 7-2, 100 Å)), a first blue EML (the compound in Formula 1-1 and the compound in Formula 1-2 (1.8 wt %), 200 Å), a first EBL (the compound in Formula 11, 100 Å), a first HTL (the compound in Formula 10-1 and the compound in Formula 10-2 (a weight % ratio=8:2), 100 Å), a first p-type CGL (the compound in Formula 10-1 and the compound in Formula 13 (10 wt %), 100 Å), a first n-type CGL (the compound in Formula 6 and Li (1.5 wt %), 100 Å), a third ETL (the compound in Formula 14, 100 Å), a red EML, a green EML, a third HTL (the compound in Formula 10-1 and the compound in Formula 10-2, 450 Å), a second p-type CGL (the compound in Formula 10-2 and the compound in Formula 13 (10 wt %), 100 Å), a second n-type CGL (the compound in Formula 6 and L₁ (1.5 wt %), 200 Å), a second ETL (a lower layer (the compound in Formula 7-1, 340 Å) and an upper layer (the compound in Formula 7-2, 100 Å)), a second blue EML (the compound in Formula 1-1 and the compound in Formula 1-2 (1.8 wt %), 300 Å), a second EBL (the compound in Formula 11, 100 Å), a second HTL (the compound in Formula 12-1 and the compound in Formula 12-2 (a weight % ratio=6:4), 100 Å), an HIL (the compound in Formula 10-1 and the compound in Formula 13 (20 wt %), 100 Å), and an anode (Al, 1000 Å) were sequentially stacked on a substrate to form an inverted-structure 3-stack white OLED.

### 10. Comparative Example 4 (Ref4)

The red EML (130 Å) was formed by using the compound in Formula 2-1 (p-type host), the compound in Formula 15 (n-type host) and the compound 2-3 (red dopant, 3.5 wt %), and the green EML (305 Å) was formed by using the compound in Formula 16 (p-type host), the compound in Formula 5-1 (n-type host) and the compound 5-2 (green dopant, 10 wt %).

### 11. Example

### (1) Example 17 (Ex17)

In the OLED of Comparative Example 4, the compound in Formula 2-2 was used instead of the compound in Formula 15.

### (2) Example 18 (Ex18)

The red EML (175 Å) was formed by using the compound in Formula 2-1 (p-type host), the compound in Formula 2-2 (n-type host) and the compound 2-3 (red dopant, 3.5 wt %), and the green EML (260 Å) was formed by using the compound in Formula 16 (p-type host), the compound in Formula 5-1 (n-type host) and the compound 5-2 (green dopant, 10 wt %). The third ETL was formed by using the compound in Formula 7-1 instead of the compound in Formula 14.

### (3) Example 19 (Ex19)

In the OLED of Example 18, the compound GHH1 in Formula 4 was used instead of the compound in Formula 16.

The emission properties, e.g., driving voltages (V1 and V2), an efficiency (cd/A), an external quantum efficiency (EQE) and a lifespan (LT), of the OLED of Comparative Example 4 and Examples 17 to 19 were measured and listed in Table 8. In Table 8, the driving voltage “V1” is a value measured at 10 mA/cm², and the driving voltage “V2” is a value measured at 100 mA/cm².

The emission intensity according to wavelength is shown in FIG. 6.

TABLE 8

| | | | | cd/A | | LT | |
|---|---|---|---|---|---|---|---|
| | V1 | V2 | EQE | R | G | R | G |
| Ref4 | 100% | 100% | 100% | 100% | 100% | 100% | 100% |
| Ex17 | 97% | 97% | 99% | 69% | 131% | 66% | 63% |
| Ex18 | 94% | 94% | 104% | 89% | 122% | 84% | 63% |
| Ex19 | 91% | 92% | 109% | 98% | 130% | 72% | 75% |

As shown in Table 8 and FIG. 6, in comparison to the n-type host of the red EML used in Comparative Example 4, the n-type host of the red EML used in Example 17 has higher electron mobility so that the driving voltage is reduced. However, in the OLED of Example 17, a property deviation in the red emission and the green emission is significant, the display quality of the organic light emitting display device is degraded.

On the other hand, in the OLED of Example 18, by increasing a thickness of the red EML and forming the third ETL by the compound in Formula 7-1, which has higher triplet energy, the driving voltage is further reduced, and a property deviation in the red emission and the green emission is decreased.

In addition, in the OLED of Example 19, by using the compound in Formula 4 as a p-type host of the green EML, the driving voltage is further reduced, and a property deviation in the red emission and the green emission is further decreased. Accordingly, the display quality of the organic light emitting display device is improved.

### OLED 9 (Example 20 (Ex20))

A cathode (ITO, 1100 Å), an EIL (the compound in Formula 6 and Li (5 wt %), 150 Å), a first ETL (a lower layer (the compound in Formula 7-1, 830 Å) and an upper layer (the compound ETM2 in Formula 9, 100 Å)), a first blue EML (the compound in Formula 1-1 and the compound in Formula 1-2 (1.8 wt %), 200 Å), a first EBL (the compound in Formula 11, 100 Å), a first HTL (the compound in Formula 10-1 and the compound in Formula 10-2 (a weight % ratio=6:4), 100 Å), a first p-type CGL (the compound in Formula 10-1 and the compound in Formula 13 (10 wt %), 100 Å), a first n-type CGL (the compound in Formula 6 and Li (1.5 wt %), 100 Å), a third ETL (the compound in Formula 7-1, 100 Å), a red EML, a green EML, a third HTL (the compound in Formula 10-1 and the compound in Formula 10-2, 450 Å), a second p-type CGL (the compound in Formula 10-2 and the compound in Formula 13 (10 wt %), 100 Å), a second n-type CGL (the compound in Formula 6 and Li (1.5 wt %), 200 Å), a second ETL (a lower layer (the compound in Formula 7-1, 340 Å) and an upper layer (the compound ETM2 in Formula 9, 100 Å)), a second blue EML (the compound in Formula 1-1 and the compound in Formula 1-2 (1.8 wt %), 300 Å), a second EBL (the compound in Formula 11, 100 Å), a second HTL (the compound in Formula 12-1 and the compound in Formula 12-2 (a weight % ratio=6:4), 100 Å), an HIL (the compound in Formula 10-1 and the compound in Formula 13 (40 wt %), 100 Å), a p-dopant layer (the compound in Formula 13, 100 Å), and an anode (Al, 1000 Å) were sequentially stacked on a substrate to form an inverted-structure 3-stack white OLED.

In the OLED9, the red EML (175 Å) was formed by using the compound in Formula 2-1 (p-type dopant), the compound 2-2 (n-type dopant) and the compound 2-3 (red dopant, 3.5 wt %), and the green EML (260 Å) was formed by using the compound GHH1 in Formula 4 (p-type dopant), the compound 5-1 (n-type dopant) and the compound 5-2 (green dopant, 10 wt %).

The emission properties, e.g., driving voltages (V1 and V2), an efficiency (cd/A), an external quantum efficiency (EQE) and a lifespan (LT), of the OLED of Comparative Example 4 and Example 20 were measured and listed in Table 9. In Table 9, the driving voltage “V1” is a value measured at 10 mA/cm², and the driving voltage “V2” is a value measured at 100 mA/cm².

TABLE 9

| | | | | cd/A | | | LT | | |
|---|---|---|---|---|---|---|---|---|---|
| | V1 | V2 | EQE | R | G | B | R | G | B |
| Ref4 | 100% | 100% | 100% | 100% | 100% | 100% | 100% | 100% | 100% |
| Ex20 | 81% | 83% | 109% | 98% | 130% | 107% | 72% | 75% | 100% |

As shown in Table 9, in the OLED of Example 20, the driving voltage is significantly decreased, and the emitting efficiency is improved.

It will be apparent to those skilled in the art that various modifications and variations can be made in the present disclosure without departing from the spirit or scope of the present disclosure. Thus, it is intended that the present disclosure cover the modifications and variations of this disclosure provided they come within the scope of the appended claims and their equivalents.

What is claimed is:

1. An organic light emitting device, comprising:
a substrate;
a cathode over the substrate;
an anode disposed over the cathode; and
an organic light emitting layer comprising a first emitting part, a second emitting part between the first emitting part and the anode and a third emitting part between the first and second emitting parts and positioned between the cathode and the anode,
wherein the first emitting part comprises a first emitting material layer, and the second emitting part comprises a second emitting material layer,
wherein the third emitting part comprises a third emitting material layer, and the third emitting material layer comprises a red emitting material layer and a green emitting material layer,
wherein the green emitting material layer comprises a first p-type host, a first n-type host and a green dopant,
wherein the first p-type host is represented by Formula 3: 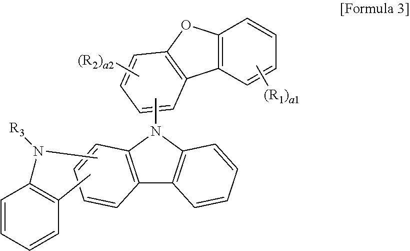
and
wherein in Formula 3,
a1 is an integer of 0 to 4, and a2 is an integer of 0 to 3, and
each of R₁, R₂ and R₃ is independently selected from the group consisting of a substituted or unsubstituted C1 to C10 alkyl group, a substituted or unsubstituted C3 to C30 cycloalkyl group, a substituted or unsubstituted C6 to C30 arylamino group, a substituted or unsubstituted C6 to C30 aryl group and a substituted or unsubstituted C3 to C30 heteroaryl group.

2. The organic light emitting device according to claim 1, wherein the first p-type host is one of compounds in Formula 4:

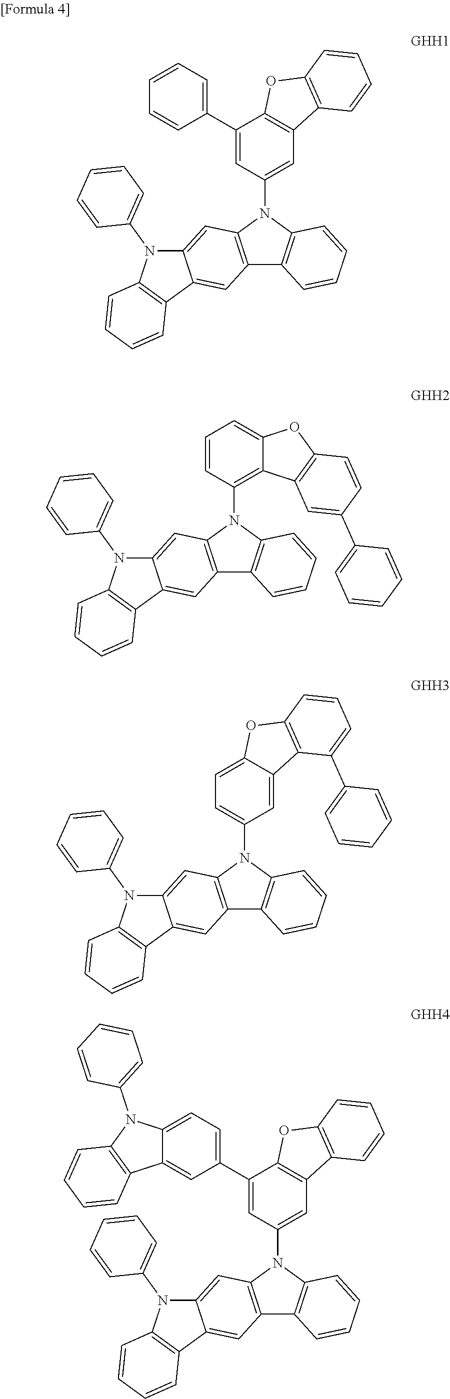

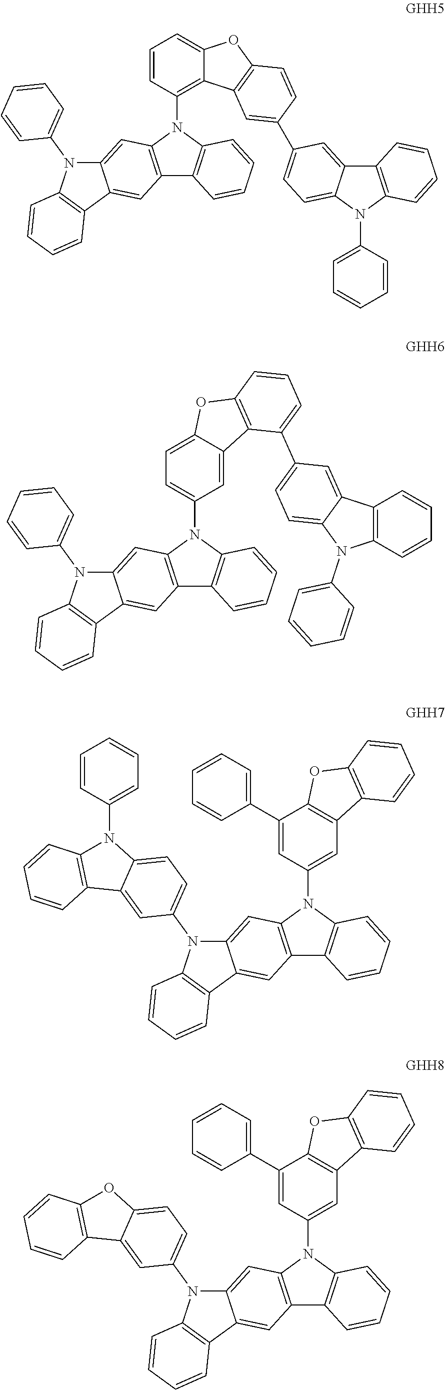 [SMILES: c1ccc(-n2c3ccccc3c3cc(-c4ccc5oc6cccc(-n7c8ccccc8c8cc9c%10ccccc%10n(-c%10ccccc%10)c9cc87)c6c5c4)ccc32)cc1 ; c1ccc(-n2c3ccccc3c3cc(-c4cccc5oc6ccc(-n7c8ccccc8c8cc9c%10ccccc%10n(-c%10ccccc%10)c9cc87)cc6c45)ccc32)cc1 ; c1ccc(-c2cc(-n3c4ccccc4c4cc5c6ccccc6n(-c6ccc7c(c6)c6ccccc6n7-c6ccccc6)c5cc43)cc3c2oc2ccccc23)cc1 ; c1ccc(-c2cc(-n3c4ccccc4c4cc5c6ccccc6n(-c6ccc7oc8ccccc8c7c6)c5cc43)cc3c2oc2ccccc23)cc1]

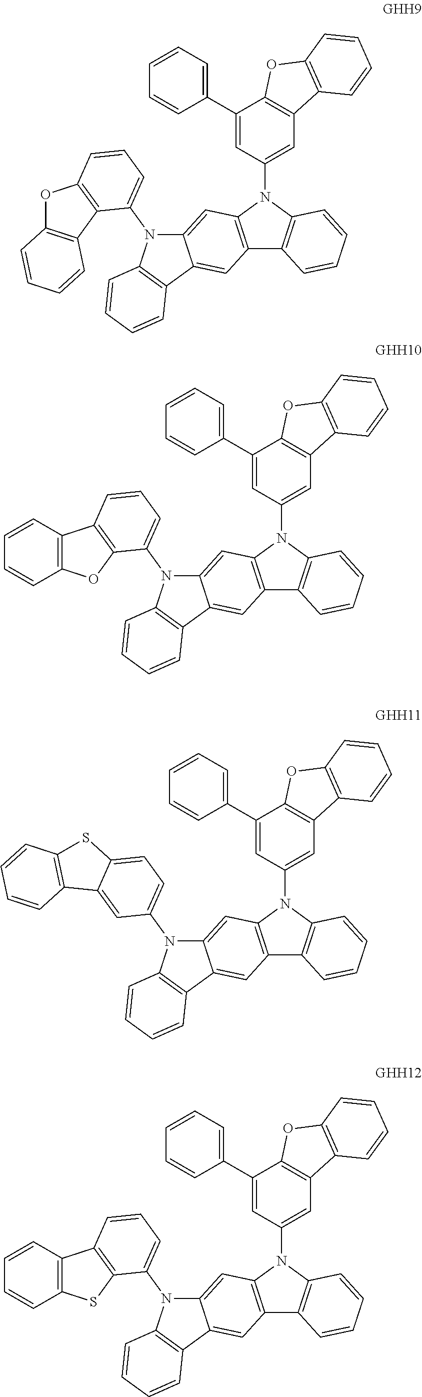 [SMILES: c1ccc(-c2cc(-n3c4ccccc4c4cc5c6ccccc6n(-c6cccc7oc8ccccc8c67)c5cc43)cc3c2oc2ccccc23)cc1 ; c1ccc(-c2cc(-n3c4ccccc4c4cc5c6ccccc6n(-c6cccc7c6oc6ccccc67)c5cc43)cc3c2oc2ccccc23)cc1 ; c1ccc(-c2cc(-n3c4ccccc4c4cc5c6ccccc6n(-c6ccc7sc8ccccc8c7c6)c5cc43)cc3c2oc2ccccc23)cc1 ; c1ccc(-c2cc(-n3c4ccccc4c4cc5c6ccccc6n(-c6cccc7c6sc6ccccc67)c5cc43)cc3c2oc2ccccc23)cc1]

3. The organic light emitting device according to claim 1, wherein the first n-type host is a compound in Formula 5-1, and the green dopant is a compound in Formula 5-2:

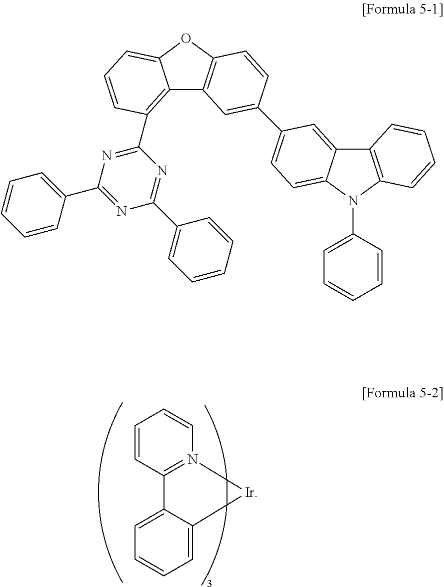

4. The organic light emitting device according to claim 1, wherein the red emitting material layer comprises a second p-type host, a second n-type host and a red dopant, and
wherein the second p-type host is a compound in Formula 2-1, the second n-type host is a compound in Formula 2-2, and the red dopant is a compound in Formula 2-3:

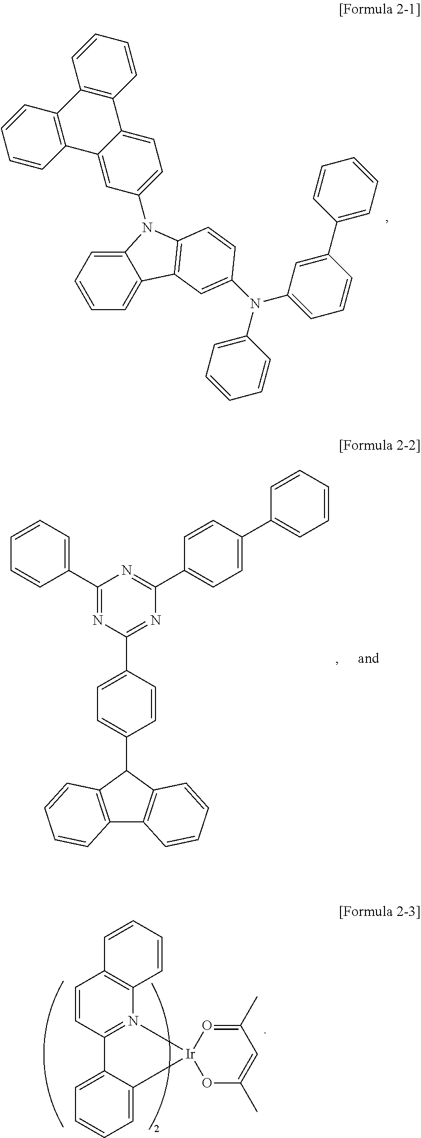

5. The organic light emitting device according to claim 1, wherein the first emitting part further comprises a first electron transporting layer between the cathode and the first emitting material layer, and the second emitting part further comprises a second electron transporting layer between the second emitting material layer and the third emitting material layer,
wherein the first electron transporting layer comprises a first lower layer having a first thickness and a first upper layer having a second thickness smaller than the first thickness, and
wherein the second electron transporting layer comprises a second lower layer having a third thickness and a second upper layer having a fourth thickness smaller than the third thickness.

6. The organic light emitting device according to claim 5, wherein each of the first and second lower layers comprises a compound in Formula 7-1, and each of the first and second upper layers comprises a compound in Formula 7-2 or a compound represented by Formula 8: 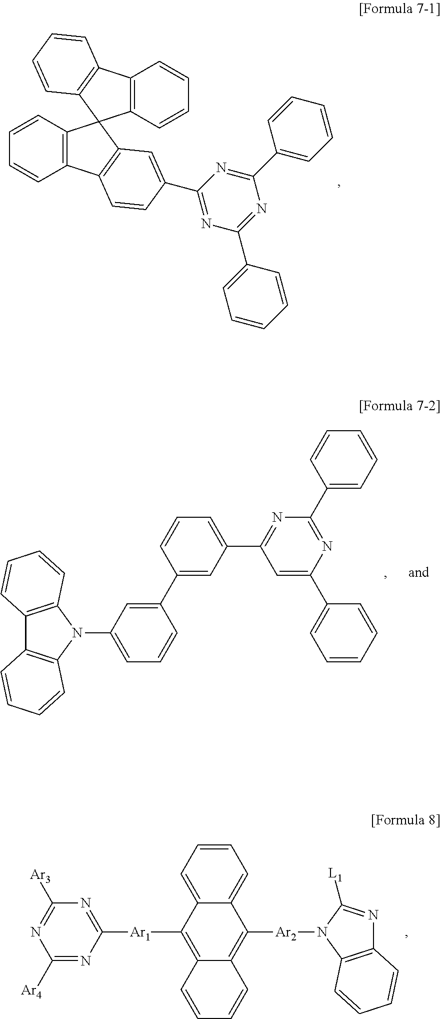
wherein in Formula 8,
each of Ar₁ and Ar₂ is independently selected from the group consisting of a single bond, a substituted or unsubstituted C6 to C30 arylene group and a substituted or unsubstituted C3 to C30 heteroarylene group,
each of Ar₃ and Ar₄ is independently selected from the group consisting of hydrogen, a substituted or unsubstituted C6 to C30 aryl group and a substituted or unsubstituted C3 to C30 heteroaryl group, and
L₁ is selected from the group consisting of a substituted or unsubstituted C1 to C10 alkyl group, a substituted or unsubstituted C3 to C30 cycloalkyl group, a substituted or unsubstituted C6 to C30 aryl group and a substituted or unsubstituted C3 to C30 heteroaryl group.

7. The organic light emitting device according to claim 6, wherein the compound represented by Formula 8 is one of compounds in Formula 9:

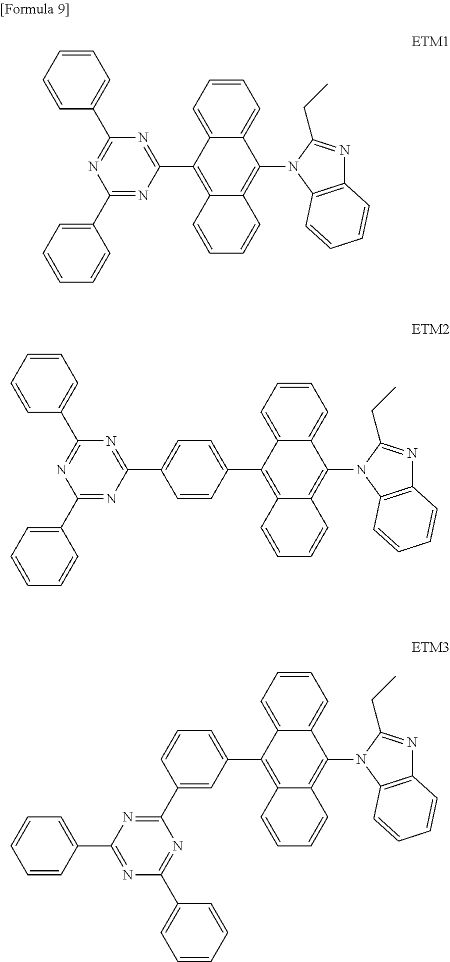 [SMILES: CCc1nc2ccccc2n1-c1c2ccccc2c(-c2nc(-c3ccccc3)nc(-c3ccccc3)n2)c2ccccc12 ; CCc1nc2ccccc2n1-c1c2ccccc2c(-c2ccc(-c3nc(-c4ccccc4)nc(-c4ccccc4)n3)cc2)c2ccccc12 ; CCc1nc2ccccc2n1-c1c2ccccc2c(-c2cccc(-c3nc(-c4ccccc4)nc(-c4ccccc4)n3)c2)c2ccccc12]

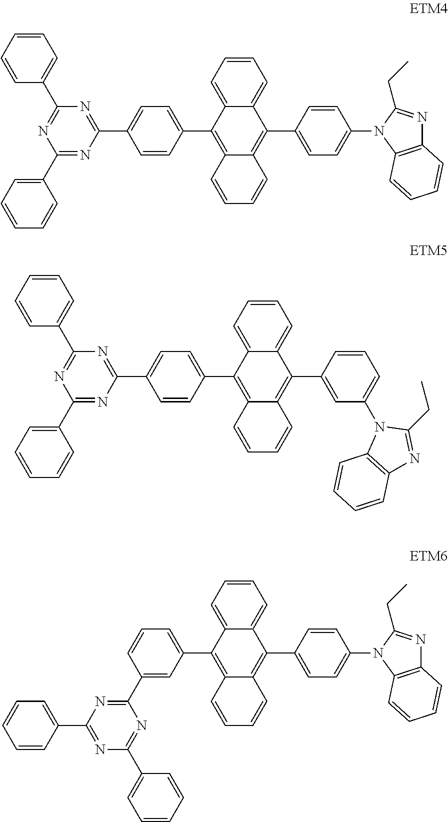 [SMILES: CCc1nc2ccccc2n1-c1ccc(-c2c3ccccc3c(-c3ccc(-c4nc(-c5ccccc5)nc(-c5ccccc5)n4)cc3)c3ccccc23)cc1 ; CCc1nc2ccccc2n1-c1cccc(-c2c3ccccc3c(-c3ccc(-c4nc(-c5ccccc5)nc(-c5ccccc5)n4)cc3)c3ccccc23)c1 ; CCc1nc2ccccc2n1-c1ccc(-c2c3ccccc3c(-c3cccc(-c4nc(-c5ccccc5)nc(-c5ccccc5)n4)c3)c3ccccc23)cc1]

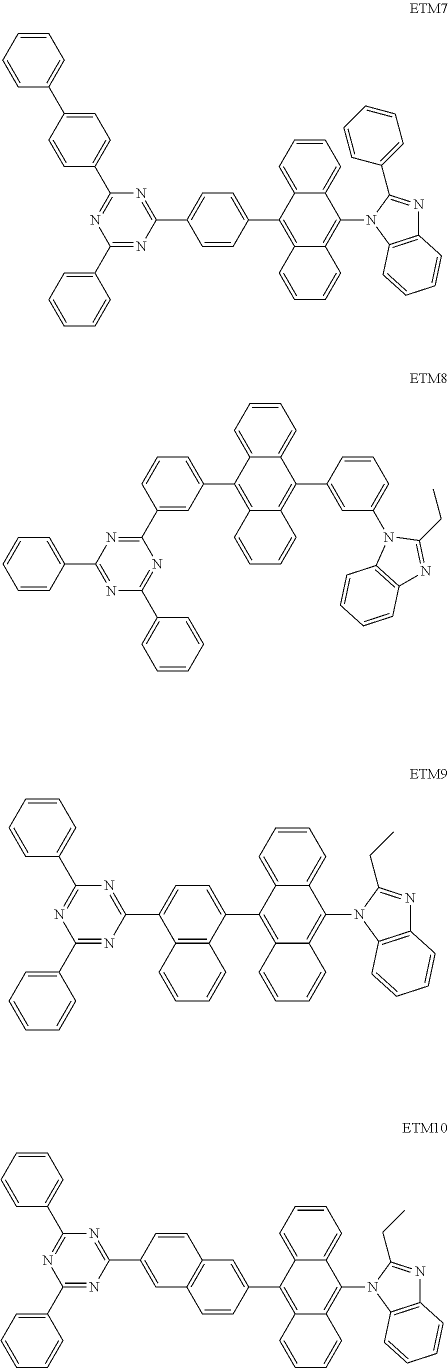 [SMILES: c1ccc(-c2ccc(-c3nc(-c4ccccc4)nc(-c4ccc(-c5c6ccccc6c(-n6c(-c7ccccc7)nc7ccccc76)c6ccccc56)cc4)n3)cc2)cc1 ; CCc1nc2ccccc2n1-c1cccc(-c2c3ccccc3c(-c3cccc(-c4nc(-c5ccccc5)nc(-c5ccccc5)n4)c3)c3ccccc23)c1 ; CCc1nc2ccccc2n1-c1c2ccccc2c(-c2ccc(-c3nc(-c4ccccc4)nc(-c4ccccc4)n3)c3ccccc23)c2ccccc12 ; CCc1nc2ccccc2n1-c1c2ccccc2c(-c2ccc3cc(-c4nc(-c5ccccc5)nc(-c5ccccc5)n4)ccc3c2)c2ccccc12]

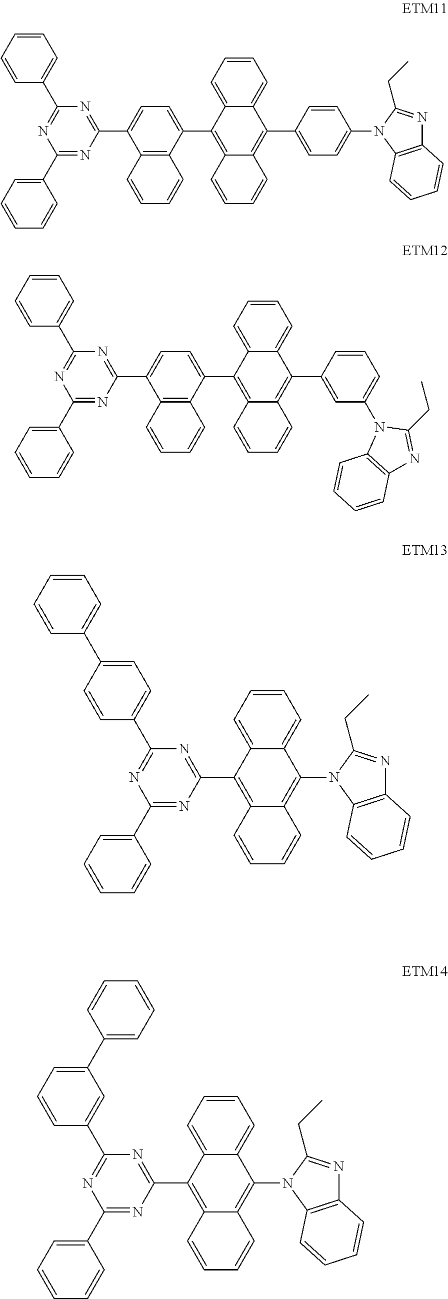 [SMILES: CCc1nc2ccccc2n1-c1ccc(-c2c3ccccc3c(-c3ccc(-c4nc(-c5ccccc5)nc(-c5ccccc5)n4)c4ccccc34)c3ccccc23)cc1 ; CCc1nc2ccccc2n1-c1cccc(-c2c3ccccc3c(-c3ccc(-c4nc(-c5ccccc5)nc(-c5ccccc5)n4)c4ccccc34)c3ccccc23)c1 ; CCc1nc2ccccc2n1-c1c2ccccc2c(-c2nc(-c3ccccc3)nc(-c3ccc(-c4ccccc4)cc3)n2)c2ccccc12 ; CCc1nc2ccccc2n1-c1c2ccccc2c(-c2nc(-c3ccccc3)nc(-c3cccc(-c4ccccc4)c3)n2)c2ccccc12]

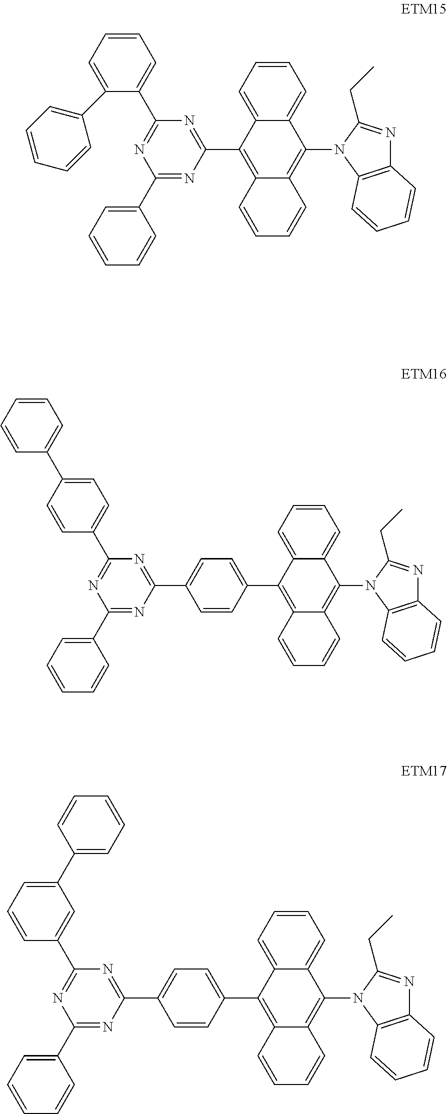 [SMILES: CCc1nc2ccccc2n1-c1c2ccccc2c(-c2nc(-c3ccccc3)nc(-c3ccccc3-c3ccccc3)n2)c2ccccc12 ; CCc1nc2ccccc2n1-c1c2ccccc2c(-c2ccc(-c3nc(-c4ccccc4)nc(-c4ccc(-c5ccccc5)cc4)n3)cc2)c2ccccc12 ; CCc1nc2ccccc2n1-c1c2ccccc2c(-c2ccc(-c3nc(-c4ccccc4)nc(-c4cccc(-c5ccccc5)c4)n3)cc2)c2ccccc12]

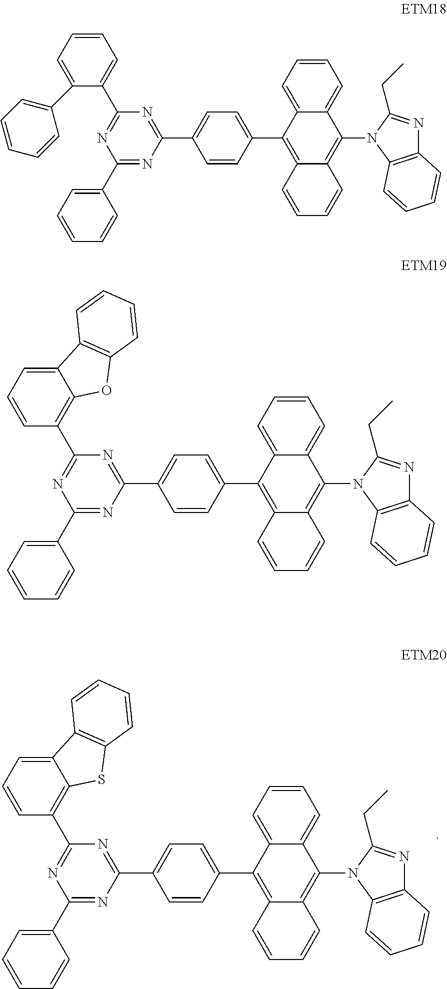 [SMILES: CCc1nc2ccccc2n1-c1c2ccccc2c(-c2ccc(-c3nc(-c4ccccc4)nc(-c4ccccc4-c4ccccc4)n3)cc2)c2ccccc12 ; CCc1nc2ccccc2n1-c1c2ccccc2c(-c2ccc(-c3nc(-c4ccccc4)nc(-c4cccc5c4oc4ccccc45)n3)cc2)c2ccccc12 ; CCc1nc2ccccc2n1-c1c2ccccc2c(-c2ccc(-c3nc(-c4ccccc4)nc(-c4cccc5c4sc4ccccc45)n3)cc2)c2ccccc12]

8. The organic light emitting device according to claim 5, wherein the first emitting part further comprises a first hole transporting layer between the first emitting part and the third emitting part, and
wherein the first hole transporting layer comprises a compound in Formula 10-1 and a compound in Formula 10-2:

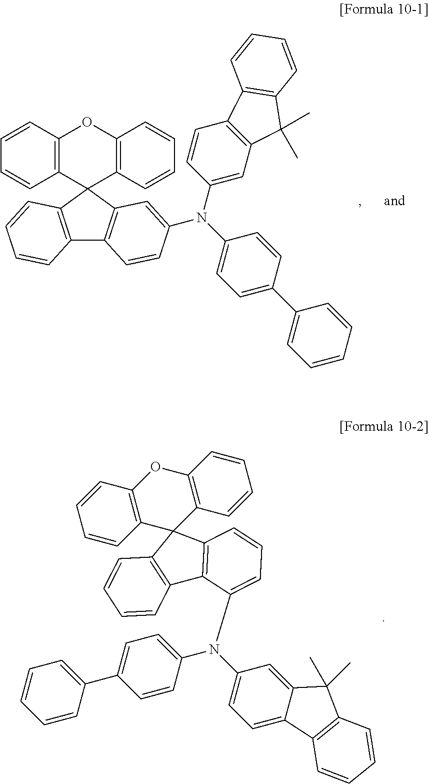 [SMILES: CC1(C)c2ccccc2-c2ccc(N(c3ccc(-c4ccccc4)cc3)c3ccc4c(c3)C3(c5ccccc5Oc5ccccc53)c3ccccc3-4)cc21 ; CC1(C)c2ccccc2-c2ccc(N(c3ccc(-c4ccccc4)cc3)c3cccc4c3-c3ccccc3C43c4ccccc4Oc4ccccc43)cc21]

9. The organic light emitting device according to claim 8, wherein the second emitting part further comprises a second hole transporting layer between the second emitting material layer and the anode, and
wherein the second hole transporting layer comprises a compound in Formula 12-1 and a compound in Formula 12-2:

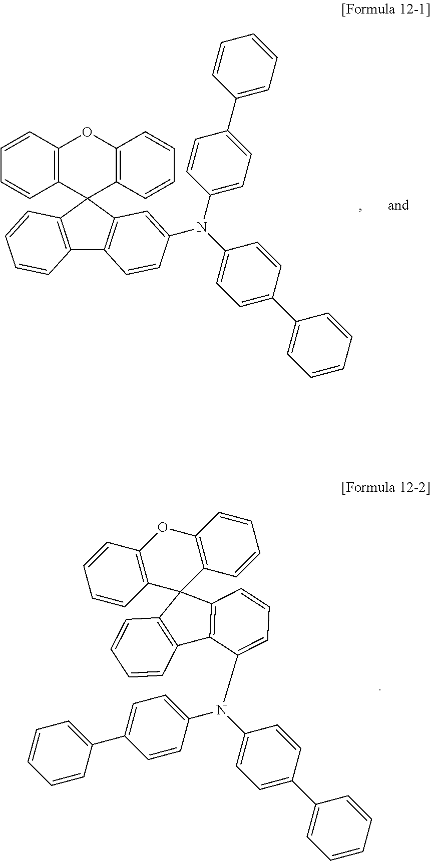 [SMILES: c1ccc(-c2ccc(N(c3ccc(-c4ccccc4)cc3)c3ccc4c(c3)C3(c5ccccc5Oc5ccccc53)c3ccccc3-4)cc2)cc1 ; c1ccc(-c2ccc(N(c3ccc(-c4ccccc4)cc3)c3cccc4c3-c3ccccc3C43c4ccccc4Oc4ccccc43)cc2)cc1]

10. The organic light emitting device according to claim 9, wherein the second emitting part further comprises a hole injection layer between the second hole transporting layer and the anode, and
wherein the hole injection layer comprises a host being a compound in Formula 10-1 and a p-type dopant being a compound in Formula 13:

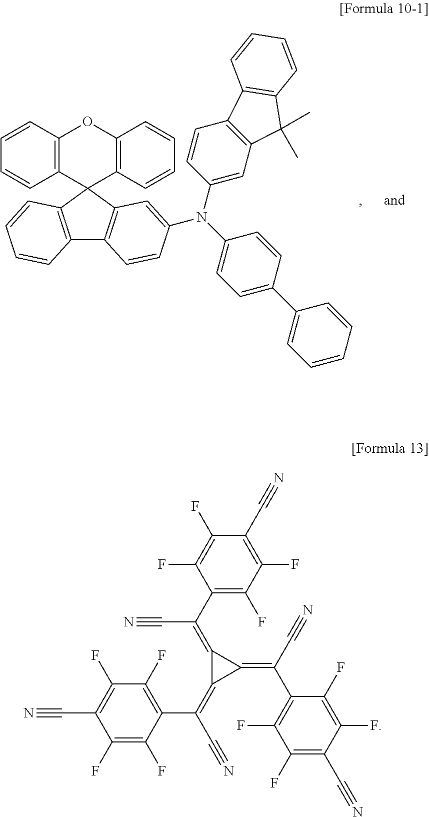 [SMILES: CC1(C)c2ccccc2-c2ccc(N(c3ccc(-c4ccccc4)cc3)c3ccc4c(c3)C3(c5ccccc5Oc5ccccc53)c3ccccc3-4)cc21 ; N#CC(=C1C(=C(C#N)c2c(F)c(F)c(C#N)c(F)c2F)C1=C(C#N)c1c(F)c(F)c(C#N)c(F)c1F)c1c(F)c(F)c(C#N)c(F)c1F]

11. The organic light emitting device according to claim 10, wherein the second emitting part further comprises a p-type dopant layer between the hole injection layer and the anode, and
wherein the p-type dopant layer comprises the p-type dopant being the compound in Formula 13 and has a thickness smaller than the hole injection layer.

12. The organic light emitting device according to claim 10, further comprising:
a first charge generation layer comprising a first p-type charge generation layer and a first n-type charge generation layer and positioned between the first emitting part and the third emitting part; and
a second charge generation layer comprising a second p-type charge generation layer and a second n-type charge generation layer and positioned between the second emitting part and the third emitting part.

13. The organic light emitting device according to claim 12, wherein the first p-type charge generation layer comprises a first host material and a first p-type dopant, and the second p-type charge generation layer comprises a second host material and a second p-type dopant, and
wherein each of a weight % of the first p-type dopant in the first p-type charge generation layer and a weight % of the second p-type dopant in the second p-type charge generation layer is smaller than a weight % of the p-type dopant in the hole injection layer.

14. The organic light emitting device according to claim 9, wherein the third emitting part further comprises a third hole transporting layer between the green emitting material layer and the second electron transporting layer, and
wherein a thickness of the third hole transporting layer is greater than each of a thickness of the first hole transporting layer and a thickness of the second hole transporting layer.

15. The organic light emitting device according to claim 5, wherein the third emitting part further comprises a third electron transporting layer between the red emitting material layer and the first emitting material layer, and
wherein a thickness of the third electron transporting layer is smaller than each of a thickness of the first electron transporting layer and a thickness of the second electron transporting layer.

16. An organic light emitting device, comprising:
a substrate;
a cathode over the substrate;
an anode disposed over the cathode; and
an organic light emitting layer comprising a first emitting part, a second emitting part between the first emitting part and the anode and a third emitting part between the first and second emitting parts and positioned between the cathode and the anode,
wherein the first emitting part comprises a first emitting material layer, and the second emitting part comprises a second emitting material layer,
wherein the first emitting part further comprises a first electron transporting layer between the cathode and the first emitting material layer, and the second emitting part further comprises a second electron transporting layer between the second emitting material layer and the third emitting material layer,
wherein the first electron transporting layer comprises a first lower layer having a first thickness of 750 Å to 850 Å, and a first upper layer having a second thickness of 50 Å to 150 Å, and
wherein the second electron transporting layer comprises a second lower layer having a third thickness of 300 Å to 400 Å and a second upper layer having a fourth thickness of 50 Å to 150 Å,
wherein the third emitting part comprises a third emitting material layer, and the third emitting material layer comprises a red emitting material layer and a green emitting material layer,
wherein the green emitting material layer comprises a first p-type host, a first n-type host and a green dopant,
wherein each of the first and second lower layers comprises a compound in Formula 7-1, and each of the first and second upper layers comprises a compound in Formula 7-2 or a compound represented by Formula 8: 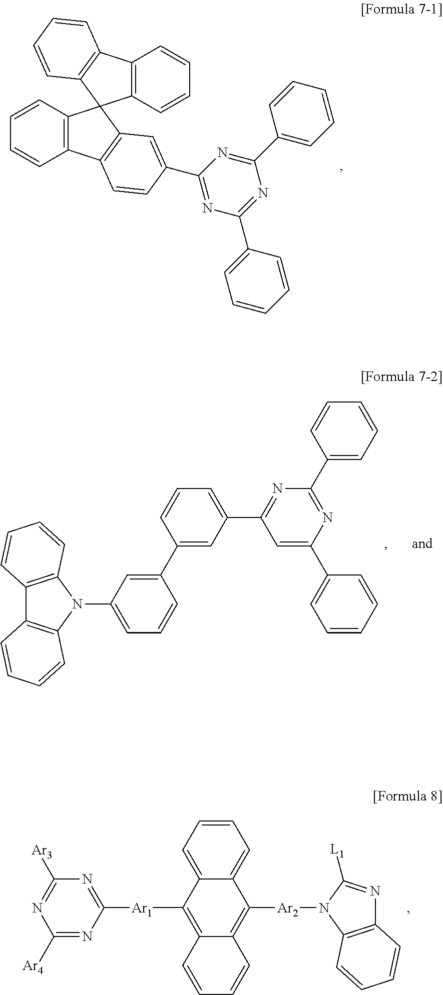
wherein in Formula 8,
each of Ar₁ and Ar₂ is independently selected from the group consisting of a single bond, a substituted or unsubstituted C6 to C30 arylene group and a substituted or unsubstituted C3 to C30 heteroarylene group,
each of Ar₃ and Ar₄ is independently selected from the group consisting of hydrogen, a substituted or unsubstituted C6 to C30 aryl group and a substituted or unsubstituted C3 to C30 heteroaryl group, and
L₁ is selected from the group consisting of a substituted or unsubstituted C1 to C10 alkyl group, a substituted or unsubstituted C3 to C30 cycloalkyl group, a substituted or unsubstituted C6 to C30 aryl group and a substituted or unsubstituted C3 to C30 heteroaryl group.

17. The organic light emitting device according to claim 16, wherein the first emitting part further comprises a first hole transporting layer between the first emitting part and the third emitting part, and
wherein the first hole transporting layer comprises a compound in Formula 10-1 and a compound in Formula 10-2:

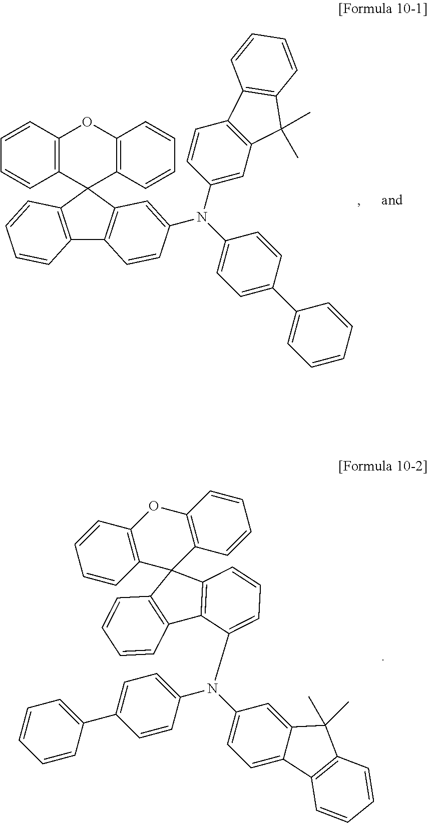 [SMILES: CC1(C)c2ccccc2-c2ccc(N(c3ccc(-c4ccccc4)cc3)c3ccc4c(c3)C3(c5ccccc5Oc5ccccc53)c3ccccc3-4)cc21 ; CC1(C)c2ccccc2-c2ccc(N(c3ccc(-c4ccccc4)cc3)c3cccc4c3-c3ccccc3C43c4ccccc4Oc4ccccc43)cc21]

18. The organic light emitting device according to claim 17, wherein the third emitting part further comprises a third hole transporting layer between the green emitting material layer and the second electron transporting layer, and
wherein a thickness of the third hole transporting layer is greater than each of a thickness of the first hole transporting later and a thickness of the second hole transporting layer.

19. The organic light emitting device according to claim 16, further comprising:
a first charge generation layer comprising a first p-type charge generation layer and a second n-type charge generation layer and positioned between the first emitting part and the third emitting part; and
a second charge generation layer comprising a second p-type charge generation layer and a second n-type charge generation layer and positioned between the second emitting part and the third emitting part,
wherein the first p-type charge generation layer comprises a first host material and a first p-type dopant, and the second p-type charge generation layer comprises a second host material and a second p-type dopant, and
wherein each of a weight % of the first p-type dopant in the first p-type charge generation layer and a weight % of the second p-type dopant in the second p-type charge generation layer is smaller than a weight % of the p-type dopant in the hole injection layer.
